(19) United States
(12) Patent Application Publication
(10) Pub. No.: US 2013/0313637 A1
(43) Pub. Date: Nov. 28, 2013

(54) TRANSISTOR AND METHOD OF MANUFACTURING THE SAME

(71) Applicant: RENESAS ELECTRONICS CORPORATION, Kawasaki-shi (JP)

(72) Inventor: Hiroshi Yoshida, Kawasaki-shi (JP)

(73) Assignee: Renesas Electronics Corporation, Kawasaki-shi (JP)

(21) Appl. No.: 13/859,243

(22) Filed: Apr. 9, 2013

(30) Foreign Application Priority Data
May 23, 2012 (JP) 2012-117354

(51) Int. Cl. H01L 27/088; H01L 21/28

(52) U.S. Cl. CPC H01L 27/088; H01L 21/28008
USPC 257/334; 438/589

(57) ABSTRACT

A transistor having a source region, a drain region, a plurality of trenches extended in the longitudinal direction of a channel between the source region and the drain region and arranged in parallel in a longitudinal direction of a channel, an epitaxial layer formed on the lateral surfaces of each of the trenches, a gate oxide film covering the epitaxial layer and a gate electrode covering the gate insulating film and filled in the trenches.

### CROSS-REFERENCE TO RELATED APPLICATIONS

The disclosure of Japanese Patent Application No. 2012-117354 filed on May 23, 2012 including the specification, drawings, and abstract is incorporated herein by reference in its entirety.

### BACKGROUND

The present invention relates to a transistor and a method of manufacturing the same.

In the course of downsizing transistors, Japanese Unexamined Patent Publication No. 2011-9578, for example, discloses a transistor in which a gate electrode is formed in a plurality of trenches extended in the longitudinal direction of a gate thereby increasing a substantial gate width. Such a transistor is referred to as a lateral trench MOSFET (Metal-Oxide-Semiconductor Field-Effect Transistor).

By the way, Japanese Unexamined Patent Publication No. 2007-5568 discloses a configuration of forming trapezoidal convex portions instead of a trench by selective epitaxial growing (unevenness is formed as a result). However, this involves problems that the substantial gate width cannot be increased by so much as in the lateral trench MOSFET of Japanese Unexamined Patent Publication No. 2011-9578, as well as that productivity is poor since the unevenness is formed by selective epitaxial growing.

As a transistor forming a gate electrode in a trench, a transistor in which a current flows in a direction perpendicular to the main surface of a semiconductor substrate has been known. Such a transistor is referred to as a vertical type MOSFET and disclosed, for example, in the Japanese Unexamined Patent Publication Nos. 2005-032792 and 2011-108713. While such a vertical type trench MOSFET is in common with the lateral type trench MOSFET in that the gate is formed in the trench, other configurations, manufacturing methods, etc. are greatly different. In Japanese Patent Unexamined Patent Publication No. 2005-032792 discloses a configuration in which a thin epitaxial layer is formed over the surface of a trench, but the epitaxial layer has a concentration profile in the direction of depth.

Further, Japanese Unexamined Patent Publication No. 2002-043570 discloses a DMOSFET (Double-Diffused MOSFET) in which a semi-elliptic trench is formed and an epitaxial layer is formed over the trench.

### SUMMARY

The present inventors have found the following subject. In the lateral trench MOSFET, the impurity concentration of a semiconductor layer in which trenches are formed is different in the direction of the depth of the trenches. Accordingly, even if a transistor is actually a single element, it has a structure as if a plurality of transistors of different threshold voltages were connected in parallel due to the difference of the impurity concentration in the channel region. Therefore, there was a problem that it is difficult to set a threshold voltage to a desired value. Other problems and new features of the invention will become apparent in view of descriptions of the present specification in conjunction with the drawings.

A transistor according to an aspect of the present invention has an epitaxial layer formed on the lateral surface of a trench.

According to the aspect described above, the threshold voltage of a transistor can be easily set to a desired value.

### BRIEF DESCRIPTION OF THE DRAWINGS

FIG. 1 is a plan view illustrating a configuration of an NMOS transistor NT according to a first embodiment;

FIG. 2A is a cross sectional view along a line IIa-IIa in FIG. 1;

FIG. 2B is a cross sectional view along a line IIb-IIb in FIG. 1;

FIG. 2C is a cross sectional view along a line IIc-IIc in FIG. 1;

FIG. 3 is a plan view illustrating a configuration of a PMOS transistor PT according to the first embodiment;

FIG. 4A is a cross sectional view along a line IVa-IVa in FIG. 3;

FIG. 4B is a cross sectional view along a line IVb-IVb in FIG. 3;

FIG. 4C is a cross sectional view along a line IVc-IVc in FIG. 3;

FIG. 5A is a cross sectional view for explaining a method of manufacturing an NMOS transistor NT and a PMOS transistor PT according to the first embodiment;

FIG. 5B is a cross sectional view for explaining the method of manufacturing the NMOS transistor NT and the PMOS transistor PT according to the first embodiment;

FIG. 5C is a cross sectional view for explaining the method of manufacturing the NMOS transistor NT and the PMOS transistor PT according to the first embodiment;

FIG. 5D is a cross sectional view for explaining the method of manufacturing the NMOS transistor NT and the PMOS transistor PT according to the first embodiment;

FIG. 5E is a cross sectional view for explaining the method of manufacturing the NMOS transistor NT and the PMOS transistor PT according to the first embodiment;

FIG. 5F is a cross sectional view for explaining the method of manufacturing the NMOS transistor NT and the PMOS transistor PT according to the first embodiment;

FIG. 5G is a cross sectional view for explaining the method of manufacturing the NMOS transistor NT and the PMOS transistor PT according to the first embodiment;

FIG. 5H is a cross sectional view for explaining the method of manufacturing the NMOS transistor NT and the PMOS transistor PT according to the first embodiment;

FIG. 6A is a cross sectional view for explaining the method of manufacturing the NMOS transistor NT and the PMOS transistor PT according to the first embodiment;

FIG. 6B is a cross sectional view for explaining the method of manufacturing the NMOS transistor NT and the PMOS transistor PT according to the first embodiment;

FIG. 6C is a cross sectional view for explaining the method of manufacturing the NMOS transistor NT and the PMOS transistor PT according to the first embodiment;

FIG. 6D is a cross sectional view for explaining the method of manufacturing the NMOS transistor NT and the PMOS transistor PT according to the first embodiment;

FIG. 7 is a cross sectional view for explaining a method of manufacturing an NMOS transistor NT and a PMOS transistor PT according to a second embodiment;

FIG. 8 is a graph showing dependence of a thickness of an insulating film IF 3 that remains inside trenches TR1 and TR2 (thickness of remaining oxide film in trench) on a trench distance;

FIG. 9A is a cross sectional view for explaining a method of manufacturing the NMOS transistor NT and the PMOS transistor PT according to the second embodiment;

FIG. 9B is a cross sectional view for explaining the method of manufacturing the NMOS transistor NT and the PMOS transistor PT according to the second embodiment;

FIG. 9C is a cross sectional view for explaining the method of manufacturing the NMOS transistor NT and the PMOS transistor PT according to the second embodiment;

FIG. 9D is a cross sectional view for explaining the method of manufacturing the NMOS transistor NT and the PMOS transistor PT according to the second embodiment;

FIG. 9E is a cross sectional view for explaining the method of manufacturing the NMOS transistor NT and the PMOS transistor PT according to the second embodiment;

FIG. 9F is a cross sectional view for explaining the method of manufacturing the NMOS transistor NT and the PMOS transistor PT according to the second embodiment;

FIG. 9G is a cross sectional view for explaining the method of manufacturing the NMOS transistor NT and the PMOS transistor PT according to the second embodiment;

FIG. 9H is a cross sectional view for explaining the method of manufacturing the NMOS transistor NT and the PMOS transistor PT according to the second embodiment;

FIG. 9I is a cross sectional view for explaining the method of manufacturing the NMOS transistor NT and the PMOS transistor PT according to the second embodiment;

FIG. 9J is a cross sectional view for explaining the method of manufacturing the NMOS transistor NT and the PMOS transistor PT according to the second embodiment;

FIG. 9K is a cross sectional view for explaining the method of manufacturing the NMOS transistor NT and the PMOS transistor PT according to the second embodiment;

FIG. 9L is a cross sectional view for explaining the method of manufacturing the NMOS transistor NT and the PMOS transistor PT according to the second embodiment;

FIG. 9M is a cross sectional view for explaining the method of manufacturing the NMOS transistor NT and the PMOS transistor PT according to the second embodiment;

FIG. 9N is a cross sectional view for explaining the method of manufacturing the NMOS transistor NT and the PMOS transistor PT according to the second embodiment;

FIG. 9O is a cross sectional view for explaining the method of manufacturing the NMOS transistor NT and the PMOS transistor PT according to the second embodiment;

FIG. 10A is a cross sectional view for explaining a method of manufacturing an NMOS transistor NT and PMOS transistor PT according to the second embodiment;

FIG. 10B is a cross sectional view for explaining the method of manufacturing the NMOS transistor NT and the PMOS transistor PT according to the second embodiment;

FIG. 10C is a cross sectional view for explaining the method of manufacturing the NMOS transistor NT and the PMOS transistor PT according to the second embodiment;

FIG. 10D is a cross sectional view for explaining the method of manufacturing the NMOS transistor NT and the PMOS transistor PT according to the second embodiment;

FIG. 11 is a view for explaining the effect of an insulating film IF3 formed over the bottom of a trench TR1;

FIG. 12 is a cross sectional view for explaining a method of manufacturing an NMOS transistor NT and a PMOS transistor PT according to a third embodiment;

FIG. 13A is a cross sectional view for explaining the method of manufacturing the NMOS transistor NT and the PMOS transistor PT according to the third embodiment;

FIG. 13B is a cross sectional view for explaining the method of manufacturing the NMOS transistor NT and the PMOS transistor PT according to the third embodiment;

FIG. 13C is a cross sectional view for explaining the method of manufacturing the NMOS transistor NT and the PMOS transistor PT according to the third embodiment;

FIG. 13D is a cross sectional view for explaining the method of manufacturing the NMOS transistor NT and the PMOS transistor PT according to the third embodiment;

FIG. 13E is a cross sectional view for explaining the method of manufacturing the NMOS transistor NT and the PMOS transistor PT according to the third embodiment;

FIG. 13F is a cross sectional view for explaining the method of manufacturing the NMOS transistor NT and the PMOS transistor PT according to the third embodiment;

FIG. 13G is a cross sectional view for explaining the method of manufacturing the NMOS transistor NT and the PMOS transistor PT according to the third embodiment;

FIG. 13H is a cross sectional view for explaining the method of manufacturing the NMOS transistor NT and the PMOS transistor PT according to the third embodiment;

FIG. 13I is a cross sectional view for explaining the method of manufacturing the NMOS transistor NT and the PMOS transistor PT according to the third embodiment;

FIG. 14A is a cross sectional view for explaining the method of manufacturing the NMOS transistor NT and the PMOS transistor PT according to the third embodiment;

FIG. 14B is a cross sectional view for explaining the method of manufacturing the NMOS transistor NT and the PMOS transistor PT according to the third embodiment;

FIG. 14C is a cross sectional view for explaining the method of manufacturing the NMOS transistor NT and the PMOS transistor PT according to the third embodiment; and

FIG. 14D is a cross sectional view for explaining the method of manufacturing the NMOS transistor NT and the PMOS transistor PT according to the third embodiment.

### DETAILED DESCRIPTION

Specific embodiments of the present invention are to be described specifically with reference to the drawings. It should be noted that the invention is not restricted to the following embodiments. Further, for making the description clearer, the following descriptions and drawings are sometimes simplified.

### First Embodiment

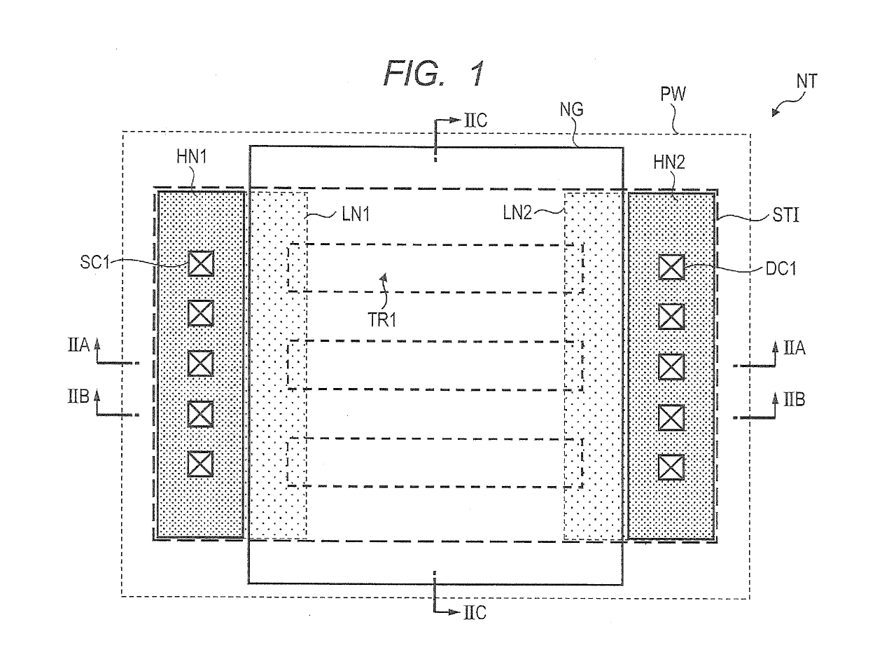

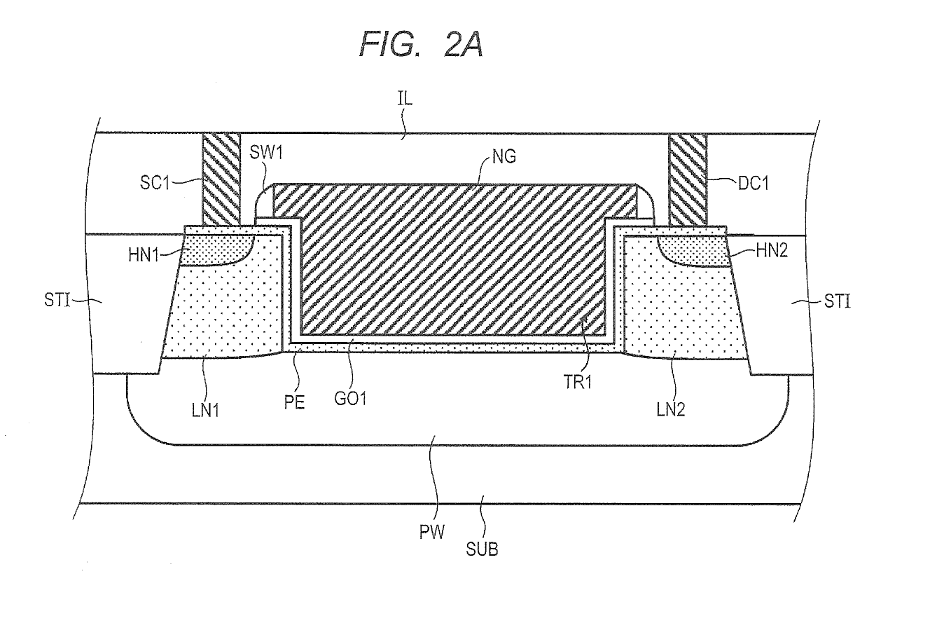

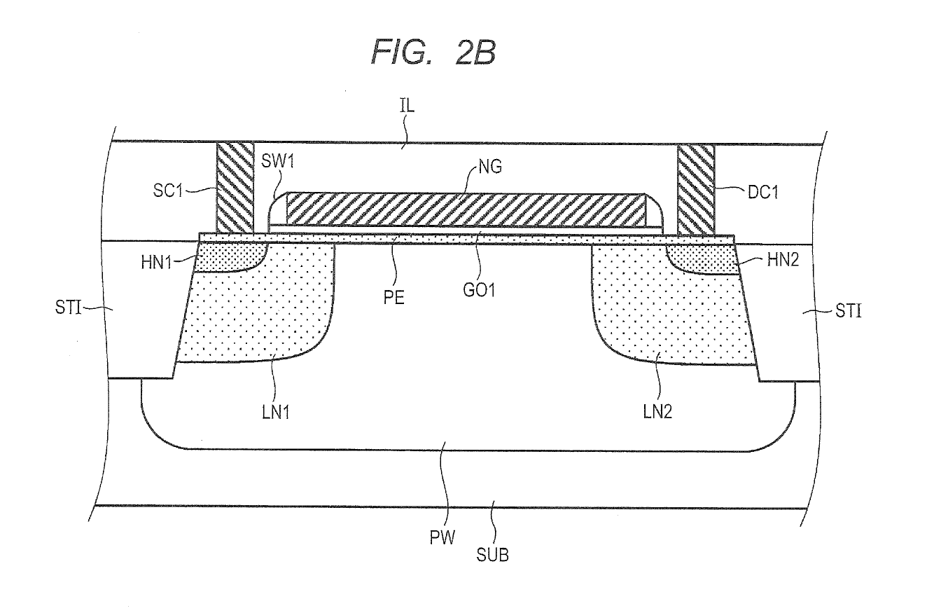

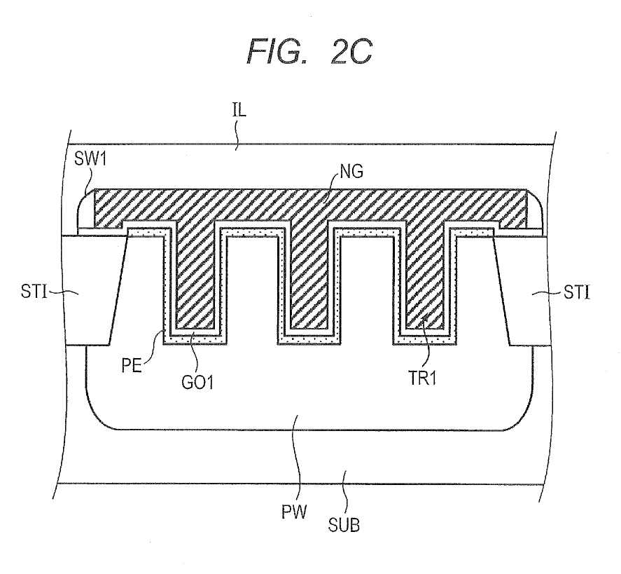

A transistor according to a first embodiment is to be described with reference to FIG. 1 and FIGS. 2A to 2C. A transistor according to the first embodiment is a lateral trench MOSFET, which is used suitably, for example, to a LCD (Liquid Crystal Display) driver in a voltage range of 10 to 20 V. FIG. 1 is a plan view illustrating a configuration of an NMOS transistor NT according to the first embodiment. FIG. 2A is a cross sectional view along a line IIa-IIa in FIG. 1. FIG. 2B is a cross sectional view along a line IIb-IIb in FIG. 1. FIG. 2C is a cross sectional view along a line IIc-IIc in FIG. 1.

As illustrated in FIG. 1, the NMOS transistor NT according to the first embodiment has a well PW. a source low impurity concentration region LN1, a drain low impurity concentration region LN2, a source high impurity concentration region HN1, a drain high impurity concentration region HN2, a device isolation layer STI, a gate electrode NG, source contacts SC1, and drain contacts DC1.

As illustrated in FIG. 2A, the NMOS transistor NT according to the first embodiment further has a semiconductor substrate SUB, a gate oxide film GO1, an epitaxial layer PE, side walls SW1, and an interlayer insulating film IL.

As can be seen from FIGS. 1, 2A and 2C, a plurality of trenches TR1 (three trenches in this embodiment) are formed to the surface of the well PW.

That is, FIG. 1 illustrates a planar positional relation for the well PW, the source low impurity concentration region LN1, the drain low impurity concentration region LN2, the device isolation layer STI, the source high impurity concentration region HN1, the drain high impurity concentration region HN2, the gate electrode NG, the source contacts SC1, and the drain contacts DC1. Accordingly, in FIG. 1, the semiconductor substrate SUB, the gate oxide film GO1, the epitaxial layer PE, the side walls SW1, and the interlayer insulating film IL are not illustrated.

In FIG. 1, a region shown by a broken line STI shows an inner edge (inner boundary line) of the device isolation layer STI. That is, the device isolation layer STI is formed to the outside of the region surrounded by the broken line STI and the device isolation layer STI is not formed to the inside thereof. The source low impurity concentration region LN1, the drain low impurity concentration region LN2, the source high impurity concentration region HN1, and the drain high impurity concentration region HN2 are formed in the region surrounded by the broken line STI. For easy understanding, the inner edge of the device isolation layer STI that actually overlaps the boundary line of the source high impurity concentration region HN1 and the drain high impurity concentration region HN2 is illustrated being displaced slightly.

First, each of the constituent elements is to be described successively with reference to FIGS. 2A to 2C.

The semiconductor substrate SUB is, for example, an N-type or P-type semiconductor substrate comprising silicon (Si). The semiconductor substrate SUB may also comprise, for example, a compound semiconductor such as silicon carbide (SiC) or gallium nitride (GaN).

The device isolation layer STI is an insulating layer formed over the semiconductor substrate SUB by, for example, an STI (Shallow Trench Isolation) method. The thickness of the device isolation layer STI can be, for example, about 300 to 1,000 nm (1 μm).

The well PW is a P-type semiconductor region formed in a region surrounded by the device isolation layer STI (device forming region) over the semiconductor substrate SUB. The P-type impurity concentration depends on depth in a range of about 1×10¹⁵ to 1×10¹⁸ atoms/cm³.

The source high impurity concentration region HN1 is an N-type high concentration semiconductor region formed on the side of the source region over the well PW. As shown in FIGS. 2A and 2B, the source high impurity concentration region HN1 is formed to a depth less than the source low impurity concentration region LN1. The depth of the source high impurity concentration region HN1 can be, for example, about 100 to 150 nm. Further, the N-type impurity concentration of the source high impurity concentration region HN1 can be about 1×10²⁰ to 1×10²² atoms/cm³. The high concentration means that the N-type impurity concentration is higher than that in the source low impurity concentration region LN1.

The source low impurity concentration region LN1 is a low concentration N-type semiconductor region formed on the side of the source region over the well PW. As shown in FIGS. 2A and 2B, the source low impurity concentration region LN1 is formed to a depth more than the source high concentration region HN1. The depth of the source low impurity concentration region LN1 can be 250 to 950 nm which is identical with or less than that of the device isolation layer STI. Further, the N-type impurity concentration of the source low impurity concentration region LN1 can be about 1×10¹⁵ to 1×10¹⁸ atoms/cm³. The low concentration means that the N-type impurity concentration is lower than that of the source high impurity concentration region HN1.

The drain high impurity concentration region HN2 is a high concentration N-type semiconductor region formed on the side of the drain region over the well PW. As shown in FIGS. 2A and 2B, the drain high impurity concentration region HN2 is formed to a depth less than the drain low impurity concentration region LN2. The depth and the N-type impurity concentration of the drain high impurity concentration region HN2 can be made about identical with those of the source high impurity concentration region HN1. The high concentration means that the N-type impurity concentration is higher than that of the drain low impurity concentration region LN2.

The drain low impurity concentration region LN2 is a low concentration N-type semiconductor region formed on the side of the drain region over the well PW. As shown in FIGS. 2A and 2B, the drain low impurity concentration region LN2 is formed to a depth more than the drain high concentration region HN2. The depth and the N-type impurity concentration of the drain low impurity concentration region LN2 can be made about identical with those of the source low concentration region LN1. The low concentration means that the N-type impurity concentration is lower than that of the drain-impurity concentration region HN2.

The source region comprises the source high impurity concentration region HN1 and the source low impurity concentration region LN1. Further, the drain region comprises the drain high impurity concentration region HN2 and the drain low impurity concentration region LN2. That is, in the NMOS transistor NT according to the first embodiment, the low impurity concentration regions LN1 and LN2 moderate an electric field intensity upon application of a high voltage to the drain or the source thereby enabling operation at high voltage.

As illustrated in FIG. 1, three trenches TR1 are formed in the surface of the well PW. Each of the three trenches TR1 is extended linearly in the longitudinal direction of a channel. The trench TR1 may have a depth of about 1 to 2 μm and a width of about 0.4 to 0.6 μm. The trench TR1 is defined with one bottom, two lateral surfaces, and two end surfaces. In the trench TR1, the bottom is parallel to the main surface of the semiconductor substrate SUB, the end surface is parallel to the cross section IIc-IIc in FIG. 1 and the lateral surface is parallel to the cross section IIa-IIa in FIG. 1.

The cross sectional shape of the trench TR1 is to be described with reference to FIGS. 2A to 2C. As illustrated in FIG. 2A, the trench TR1 is extended from the vicinity of the source high impurity concentration region HN1 to the vicinity of the drain-impurity concentration region HN2 along the cross section IIa-IIa in FIG. 1. As illustrated in FIG. 2B, the trench is not formed along the cross section IIb-IIb in FIG. 1. As illustrated in FIG. 2C, three trenches TR1 are arranged each at a substantially equal distance in the direction of the channel width along cross section IIc-IIc in FIG. 2.

A gate electrode NG is formed so as to cover and fill the trench TR1 as illustrated in FIGS. 2A and 2B. By forming the gate electrode NG over the trench TR1, the substantial gate width (channel width) can be increased without enlarging the device size.

Further, the gate electrode NG is formed over the well PW by way of an epitaxial layer PE and a gate oxide film GO1 as illustrated in FIG. 2A to FIG. 2C. Further, the gate electrode NG is formed between the source high impurity concentration region HN1 and the drain high impurity concentration region HN2 as illustrated in FIG. 1. The gate electrode NG comprises polycrystal silicon doped with N-type impurities, for example, of about 1×10²⁰ to 5×10²¹ atoms/cm³.

The epitaxial layer PE is a P-type semiconductor layer formed over the entire surface of the well PW (including the source low concentration impurity region LN1, the source high impurity concentration region HN1, the drain low impurity concentration region LN2, and the drain high impurity concentration region HN2). The thickness of epitaxial layer PE can be, for example, about 50 to 100 nm. Further, the P-type impurity concentration of the epitaxial layer PE can be about 1×10¹⁶ to 1×10¹⁸ atoms/cm³.

When a gate voltage is applied, a channel region is formed in the epitaxial layer PE which is situated between the source low impurity concentration region LN1 and the drain low impurity concentration region LN2 and situated below the gate electrode NG (refer to FIG. 2A, FIG. 2B).

The impurity concentration of the well PW has a concentration distribution that depends on the depth of the trench TR1. The concentration is different by about ten times at the maximum between the position for the highest concentration and the position for the lowest concentration. In the existent lateral trench MOSFET, since the epitaxial layer PE is not provided, even a transistor which is actually a single element has a structure as if a plurality of transistors of different threshold voltages were connected in parallel owing to different impurity concentration in the channel region. Therefore, it was difficult to set a threshold voltage of the transistor to a desired value

On the contrary, the NMOS transistor NT according to this embodiment has the epitaxial layer PE on the lateral surface of the trench TR1 that serves as the channel region. The epitaxial layer PE has less variation of the impurity concentration than the well PW at least in the direction of the depth of the trench (within 5% inside the epitaxial layer PE). Accordingly, the threshold voltage of the transistor can be set easily to a desired value.

Side walls SW1 are formed on the lateral surfaces of the gate electrode NG.

The interlayer insulating film IL is formed so as to cover the gate electrode NG.

The source contacts SC1 and the drain contacts DC1 are formed in contact holes formed in the interlayer insulating film IL. The source contacts SC1 are in contact with the epitaxial layer PE over the source high impurity concentration region HN1 and the drain contacts DC1 are in contact with the epitaxial layer PE over the drain high impurity concentration region HN2, respectively. The epitaxial layer PE present over the source and drain high impurity concentration regions HN1 and HN2 has an identical conduction type with that of the source and drain high impurity concentration regions HN1 and HN2. A metal silicide layer is preferably formed over the contact surface with the source contacts SC1 and the drain contacts DC1 of the epitaxial layer PE.

Then, with reference to FIG. 1, planar positional relation is to be described for the well PW, the source low impurity concentration region LN1, the drain low impurity concentration region LN2, the source high impurity concentration region HN1, the drain high impurity concentration region HN2, the gate electrode NG, the source contacts SC1, and the drain contacts DC1.

As shown in FIG. 1, the well PW is formed in a planar rectangular shape.

The device forming region is a rectangular region surrounded by the device isolation layer STI in the inside of the well PW.

The source high impurity concentration region HN1 is extended along the inside of the first side of the rectangular source defined by the device forming region.

The source low impurity concentration region LN1 is a region of a planar rectangular shape including the source high impurity concentration region HN1 and formed from the first side to the vicinity of the source end surface of the trench TR1. Specifically, the source low impurity concentration region LN1 is extended along the inside of the first side for a length substantially equal with the source high impurity concentration region HN1. Further, the source low impurity concentration region LN1 is formed for a large width so as to extend further to the gate electrode NG than the source high concentration impurity HN1.

The drain high impurity concentration region HN2 is extended along the inside of the second side of the drain opposing the first side.

The drain low impurity concentration region LN2 is a region of a planar rectangular shape including the drain high impurity concentration region HN2 and formed from the second side to the vicinity of the drain end surface of the trench TR1. Specifically, the drain low impurity concentration region LN2 is extended along the inside of the second side for a length substantially equal with the drain high impurity concentration region HN2. Further, the drain low impurity concentration region LN2 is formed for a large width so as to extend further to the gate electrode NG than the drain high concentration impurity HN2.

The source high impurity concentration region HN1 and the drain high impurity concentration region HN2 are opposed to each other by way of the gate electrode NG in the device forming region surrounded by the device isolation layer STI.

The gate electrode NG is formed between the source high impurity concentration region HN1 and the drain high impurity concentration region HN2 in the inside of the region for forming the well PW. The gate electrode NG is formed so as to be substantially in contact with the source high impurity concentration region HN1 and the drain high impurity concentration region HN2.

Five source contacts SC1 are each arranged substantially at an equal distance in the longitudinal direction of the source high impurity concentration region HN1.

Five drain contacts DC1 are each arranged substantially at an equal distance in the longitudinal direction of the drain high impurity concentration region HN2.

As a matter of fact, numbers and distance of arrangement of the source contacts SC1 and the drain contacts DC1 are determined optionally.

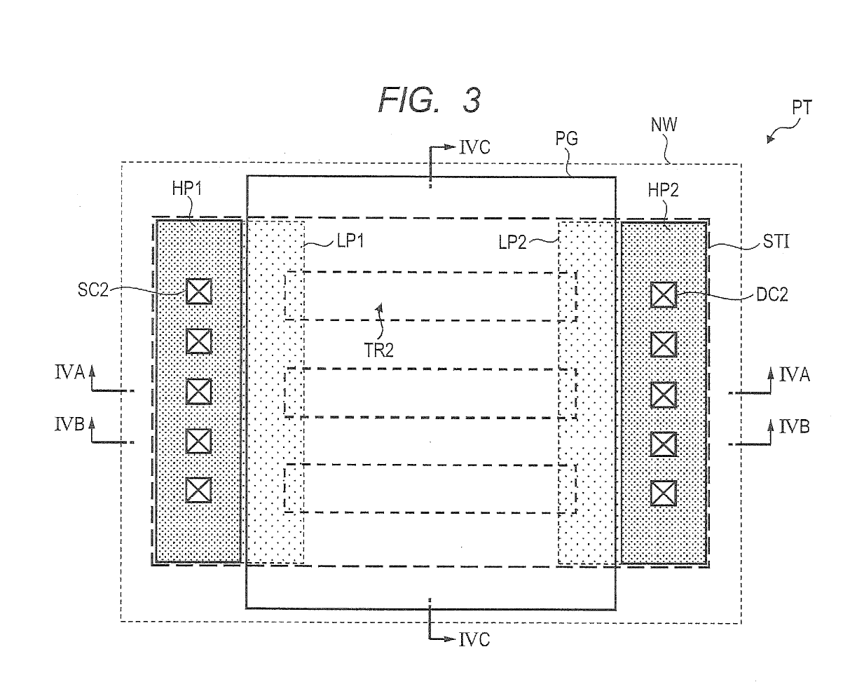

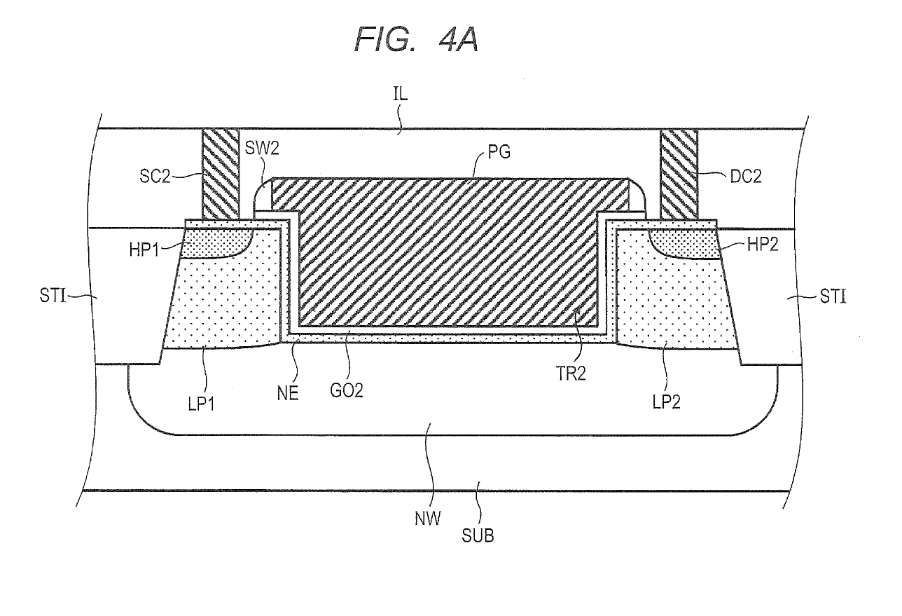

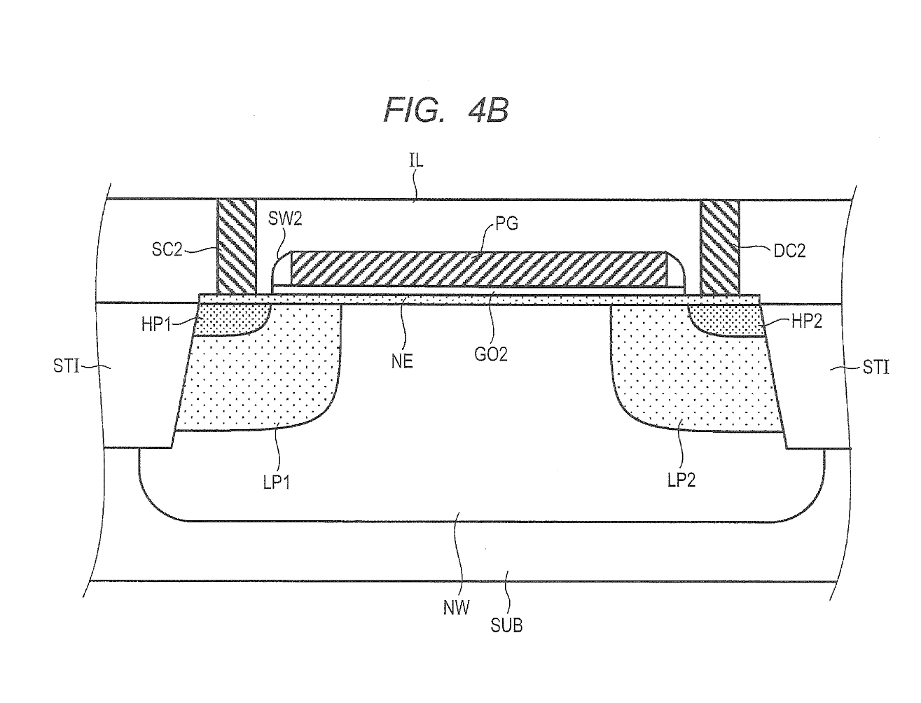

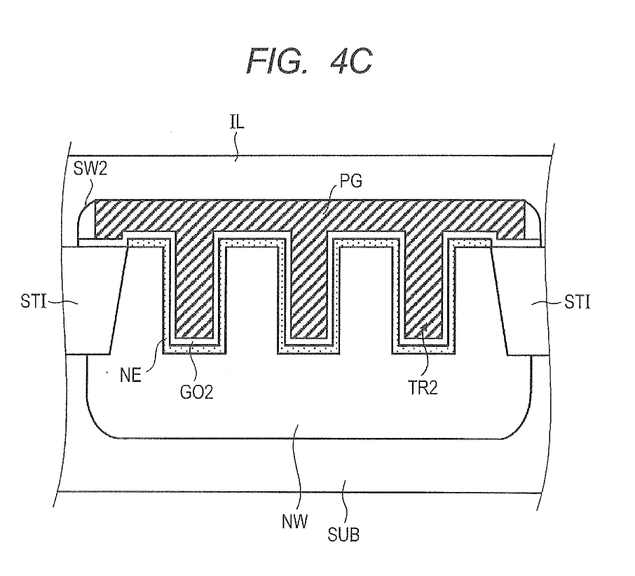

Then, a PMOS transistor PT according to the first embodiment is to be described with reference to FIG. 3 and FIGS. 4A to 4C. FIG. 3 is a plan view illustrating the configuration of the PMOS transistor PT according to the first embodiment. FIG. 4A is a cross sectional view along a line IVa-IVa in FIG. 3. FIG. 4B is a cross sectional view along a line IVb-IVb in FIG. 3. FIG. 4C is a cross sectional view along a line IVc-IVc in FIG. 3.

The PMOS transistor PT according to the first embodiment basically has the same configuration as that of the NMOS transistor NT according to the first embodiment excepting that the conduction type is different. Further, the PMOS transistor PT is formed on the semiconductor substrate SUB which is identical with that of the NMOS transistor NT. In the following description, constituent elements identical with those of the NMOS transistor NT carry the same reference numerals for which description is sometimes omitted.

As illustrated in FIG. 3, the PMOS transistor PT according to the first embodiment has a well NW. a source low impurity concentration region LP1, a drain low impurity concentration region LP2, a source high impurity concentration region HP1, a drain high impurity concentration region HP2, a device isolation layer STI, a gate electrode PG, source contacts SC2, and drain contacts DC2.

As illustrated in FIG. 4A, the PMOS transistor PT according to the first embodiment further has a semiconductor substrate SUB, a gate oxide film GO2, an epitaxial layer NE, side walls SW2, and an interlayer insulating film IL.

As can be seen from FIG. 3, and FIGS. 4A and 4C, a plurality of trenches TR2 (three trenches in this embodiment) are formed over the surface of the well NW.

That is, FIG. 3 illustrates a planar positional relation for the well NW, the source low impurity concentration region LP1, the drain low impurity concentration region LP2, the device isolation layer STI, the source high impurity concentration region HP1, the drain high impurity concentration region HP2, the gate electrode PG, the source contacts SC2, and the drain contacts DC2. Accordingly, in FIG. 3, the semiconductor substrate SUB, the gate oxide film GO2, the epitaxial layer NE, the side walls SW2, and the interlayer insulating film IL are not illustrated.

First, each of constituent elements is to be described successively with reference to FIGS. 4A to 4C.

The well NW is an N-type semiconductor region formed in a region surrounded by the device isolation layer STI (device forming region) over the semiconductor substrate SUB. The N-type impurity concentration depends on the depth in a range of about 1×10¹⁵ to 1×10¹⁸ atoms/cm³.

The source high impurity concentration region HP1 is a P-type high concentration semiconductor region formed on the side of the source region over the well NW. As shown in FIGS. 4A and 4B, the source high impurity concentration region HP1 is formed to a depth less than the source low impurity concentration region LP1. The depth of the source high impurity concentration region HP1 can be, for example, about 100 to 150 nm. Further, the P-type impurity concentration of the source high impurity concentration region HP1 can be about 1×10²⁰ to 1×10²² atoms/cm³.

The source low impurity concentration region LP1 is a low concentration P-type semiconductor region formed in the source region over the well NW. As illustrated in FIGS. 4A and 4B, the source low impurity concentration region LP1 is formed to a depth more than the source high impurity concentration region HP1. The depth of the source low impurity concentration region LP1 can be 250 to 950 nm, which is identical with or less than that of the device isolation layer STI. Further, the P-type impurity concentration of the source low impurity concentration region LP1 can be about 1×10¹⁵ to 1×10¹⁸ atoms/cm³.

The drain high impurity concentration region HP2 is a high concentration P-type semiconductor region in the drain region over the well NW. As shown in FIGS. 4A and 4B, the drain high impurity concentration region HP2 is formed to a depth less than the drain low impurity concentration region LP2. The depth and the P-type impurity concentration of the drain high impurity concentration region HP2 can be made substantially identical with those of the source high impurity concentration region HP1.

The drain low impurity concentration region LP2 is a low concentration P-type semiconductor region formed in the drain region over the well NW. As shown in FIGS. 4A and 4B, the drain low impurity concentration region LP2 is formed to a depth more than the drain high impurity concentration region HP2. The depth and the P-type impurity concentration of the drain low impurity concentration region LP2 can be made about identical with those of the source low impurity concentration region LP1.

The source region comprises the source high impurity concentration region HP1 and the source low impurity concentration region LP1. The drain region comprises the drain high impurity concentration region HP2 and the drain low impurity concentration region LP2. That is, in the PMOS transistor PT according to the first embodiment, the low impurity concentration regions LP1 and LP2 moderate an electric field intensity upon application of a high voltage to the drain or the source thereby enabling operation at high voltage.

As illustrated in FIG. 3, trenches TR2 are formed on the surface of the well NW. The shape, etc. of the trench TR2 are identical with those of the trench TR1. The cross sectional shape of the trench TR2 is to be described with reference to FIGS. 4A to 4C. As illustrated in FIG. 4A, the trench TR2 is extended from the vicinity of the source high impurity concentration region HP1 to the vicinity of the drain high impurity concentration region HP2 along the cross section IVa-IVa in FIG. 3. As illustrated in FIG. 4B, the trench is not formed along the cross section IIb-IIb in FIG. 3. As illustrated in FIG. 4C, three trenches TR2 are arranged each at a substantially equal lateral distance in the direction of the channel along the cross section IVc-IVc in FIG. 4.

The gate electrode PG is formed so as to cover and fill the trenches TR2 as illustrated in FIGS. 4A and 4C. By forming the gate electrode PG over the trenches TR2, the substantial gate width (channel width) can be increased without enlarging the device size.

Further, the gate electrode PG is formed over the well NW by way of an epitaxial layer NE and a gate oxide film GO2 as illustrated in FIG. 4A to FIG. 4C. Further, the gate electrode PG is formed between the source high impurity concentration region HP1 and the drain high impurity concentration region HP2 as illustrated in FIG. 3. The gate electrode PG comprises polycrystal silicon doped with P-type impurities, for example, of about 1×10²⁰ to 5×10²¹ atoms/cm³.

The epitaxial layer NE is an N-type semiconductor layer formed over the entire surface of the well NW (including the source low impurity concentration region LP1, the source high impurity concentration region HP1, the drain low impurity concentration region LP2, and the drain high impurity concentration region HP2). The thickness of epitaxial layer NE can be, for example, about 50 to 100 nm. Further, the N-type impurity concentration of the epitaxial layer NE can be about 1×10¹⁷ to 5×10¹⁸ atoms/cm³.

When a gate voltage is applied, a channel region is formed in the epitaxial layer NE which is situated between the source low impurity concentration region LP1 and the drain low impurity concentration region LP2 and situated below the gate electrode PG (refer to FIG. 4A, FIG. 4B).

The PMOS transistor PT according to this embodiment has the epitaxial layer NE on the lateral surface of the trench TR2 that serves as the channel region. The epitaxial layer NE has less variation of the impurity concentration than the well NW at least in the direction of the depth of the trench (within 5% inside the epitaxial layer NE). Accordingly, a threshold voltage of the transistor can be set easily to a desired value.

Side walls SW2 are formed on the lateral surfaces of the gate electrode PG.

The contacts SC2 and the drain contacts DC2 are formed in contact holes formed in the interlayer insulating film IL. The source contacts SC2 are in contact with the epitaxial layer NE over the source high impurity concentration region HP1 and the drain contacts DC2 are in contact with the epitaxial layer NE over the drain high impurity concentration region HP2, respectively. The epitaxial layer NE present over the source and drain high impurity concentration regions HP1 and HP2 has a conduction type identical with that of the source and drain high impurity concentration regions HP1 and HP2. A metal silicide layer is preferably formed over the contact surface of the epitaxial layer NE with the source contacts SC2 and the drain contacts DC2.

Since a planar positional relation for the well NW, the source low impurity concentration region LP1, the drain low impurity concentration region LP2, the source high impurity concentration region HP1, the drain high impurity concentration region HP2, the gate electrode PG, the source contacts SC2, and the drain contacts DC2 illustrated in FIG. 3 is identical with the planar positional relation for the well PW, the source low impurity concentration region LN1, the drain low impurity concentration region LN2, the source high impurity concentration region HN1, the drain high impurity concentration region HN2, the gate electrode NG, the source contacts SC1, and the drain contacts DC1 illustrated in FIG. 1, detailed description therefor is to be omitted.

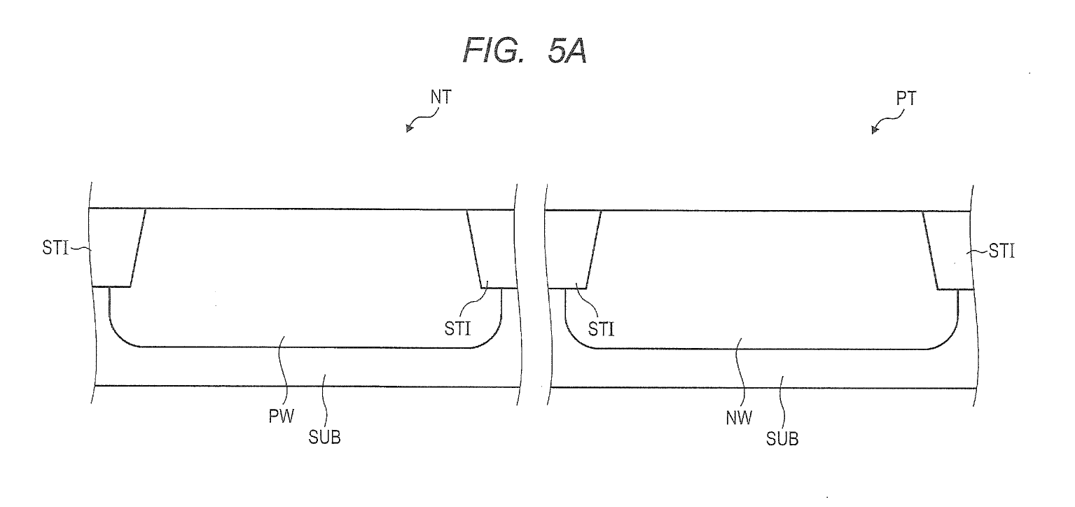

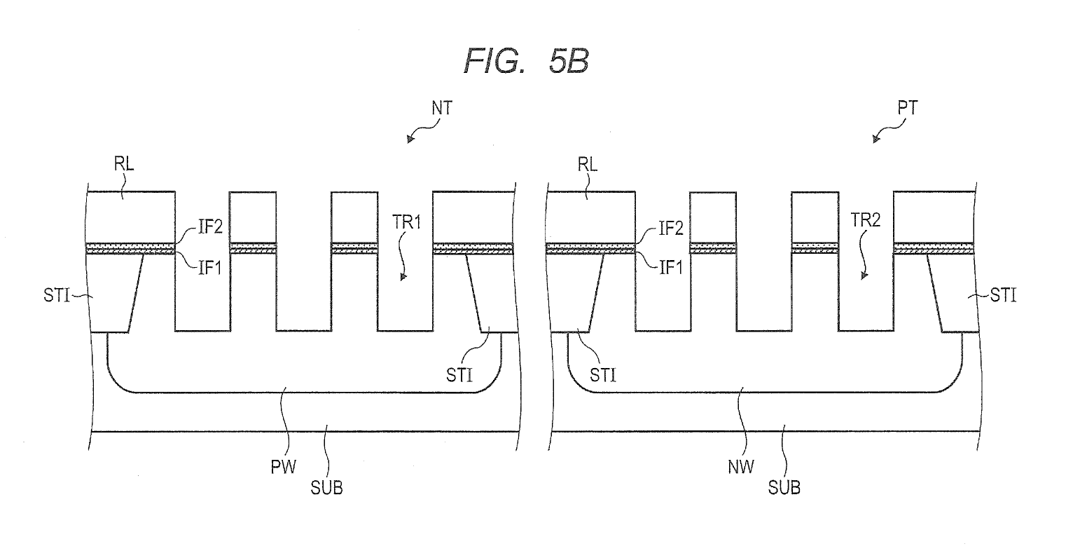

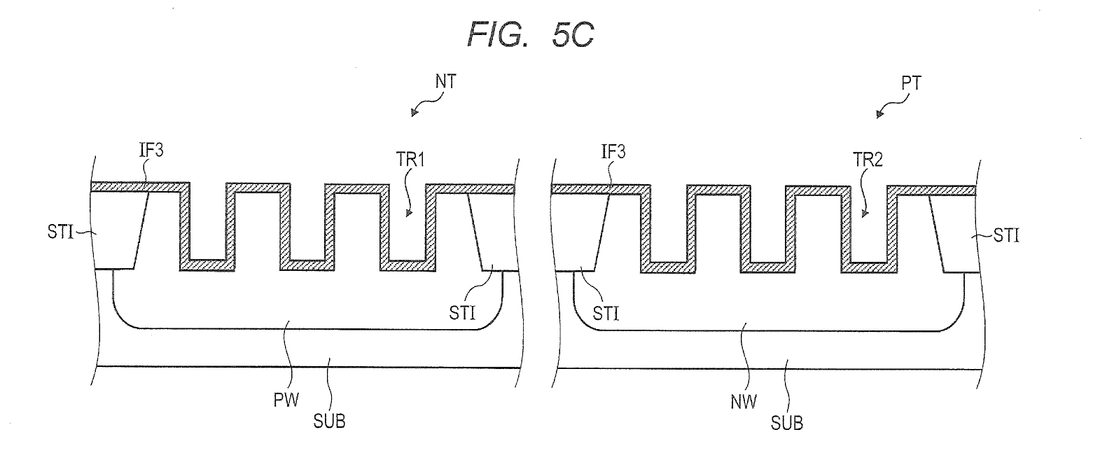

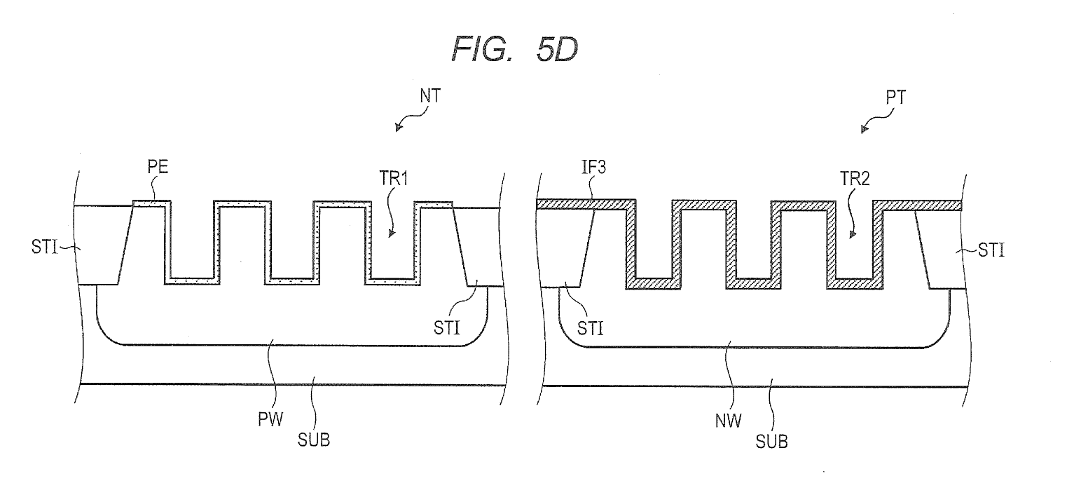

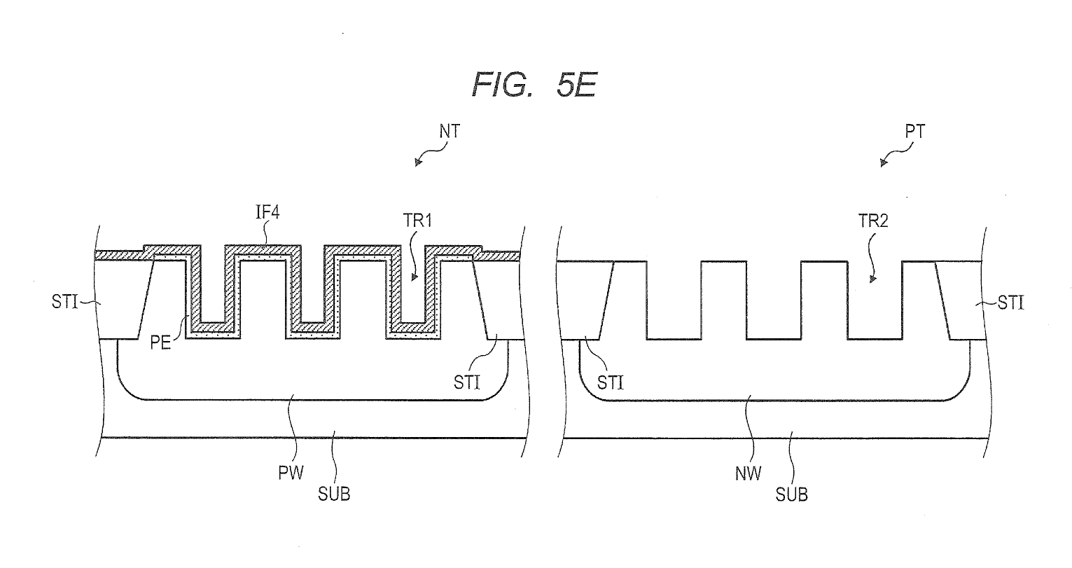

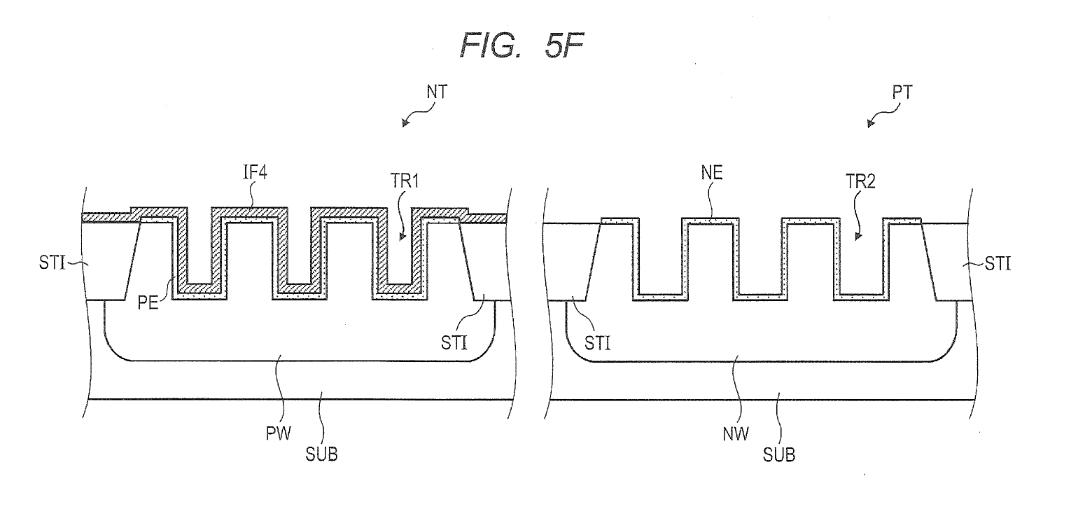

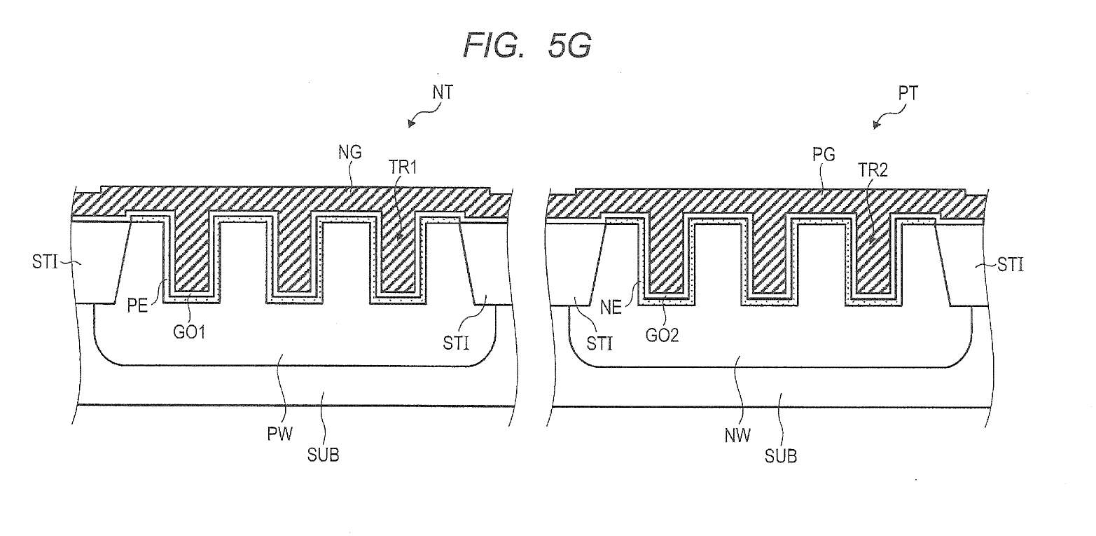

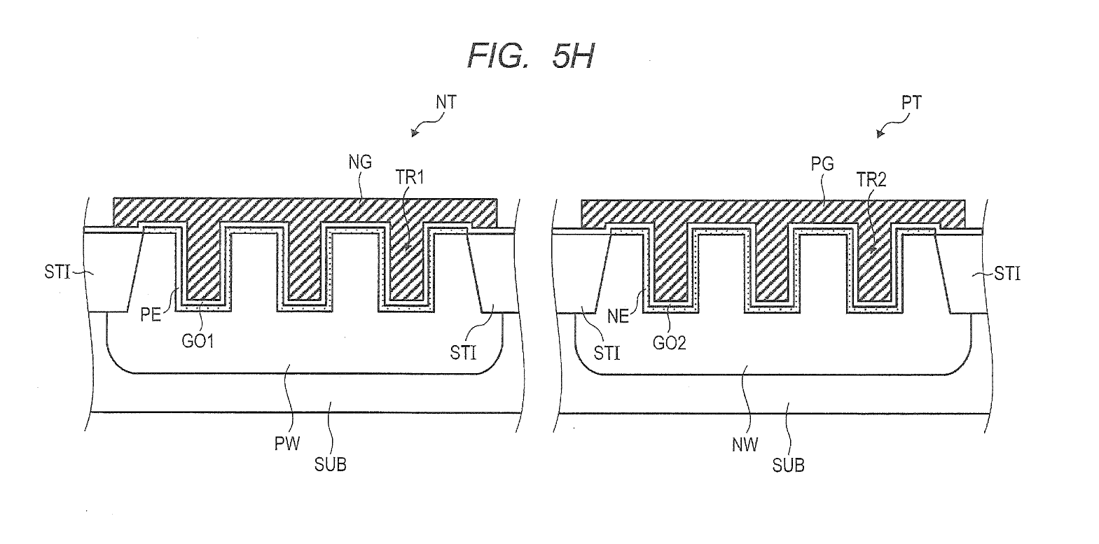

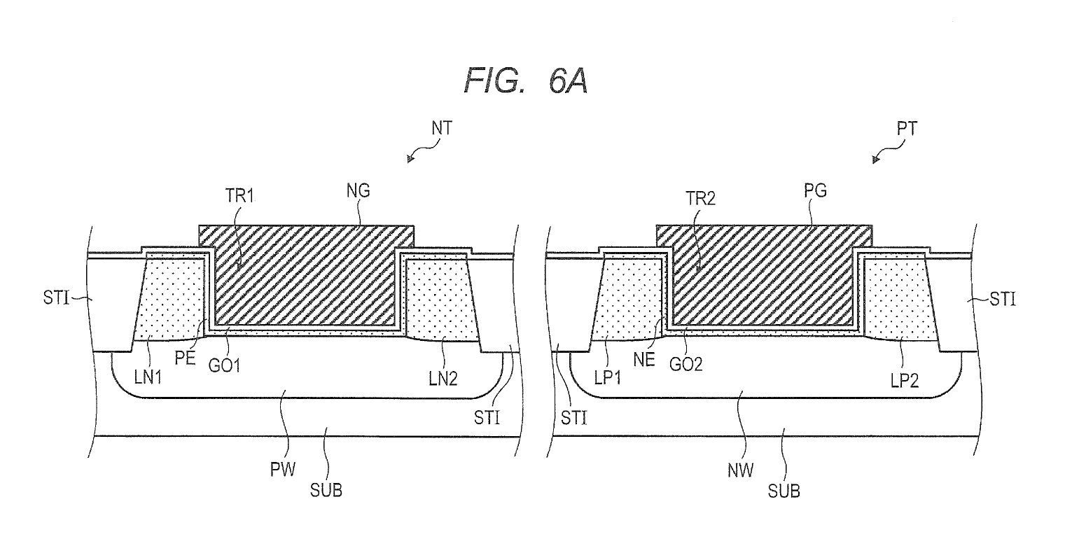

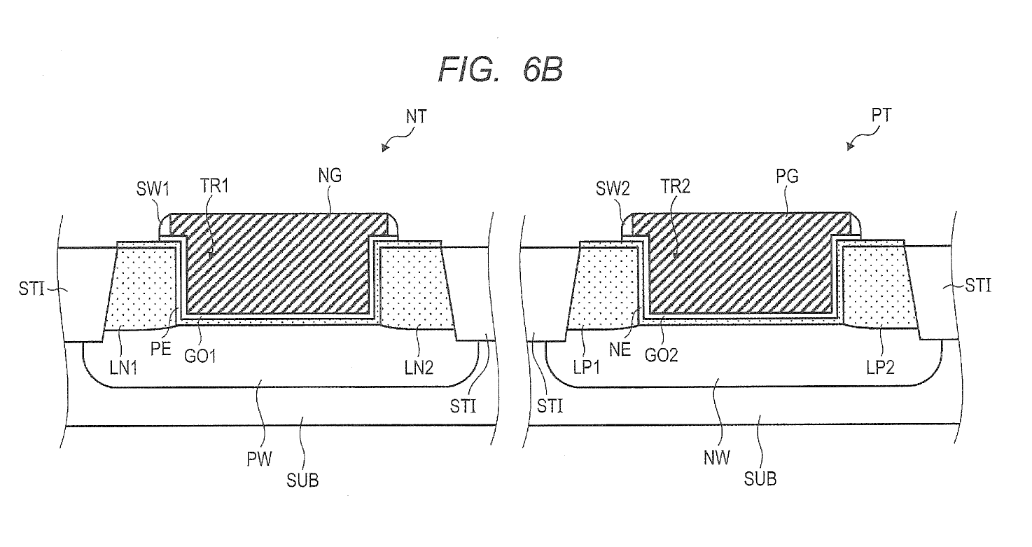

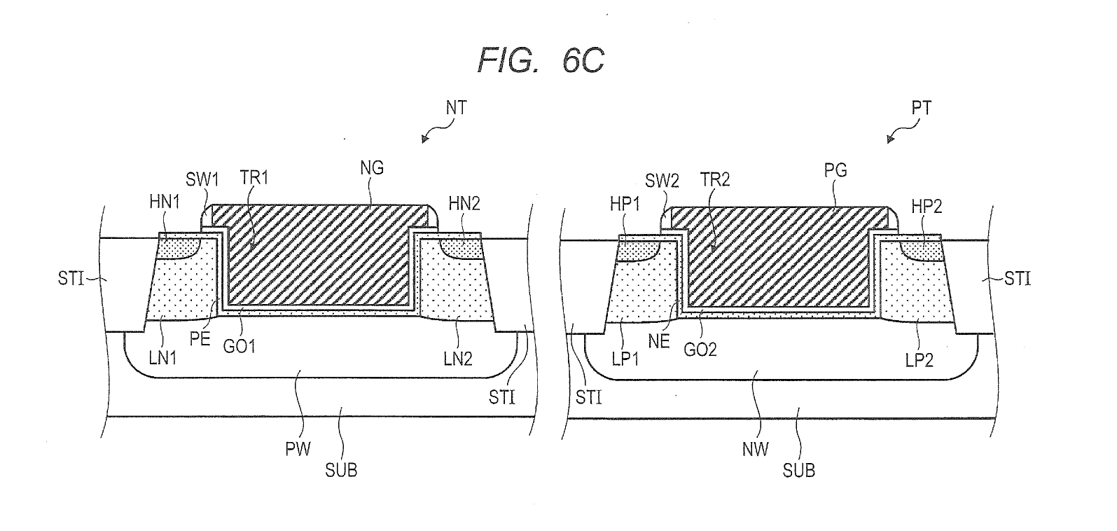

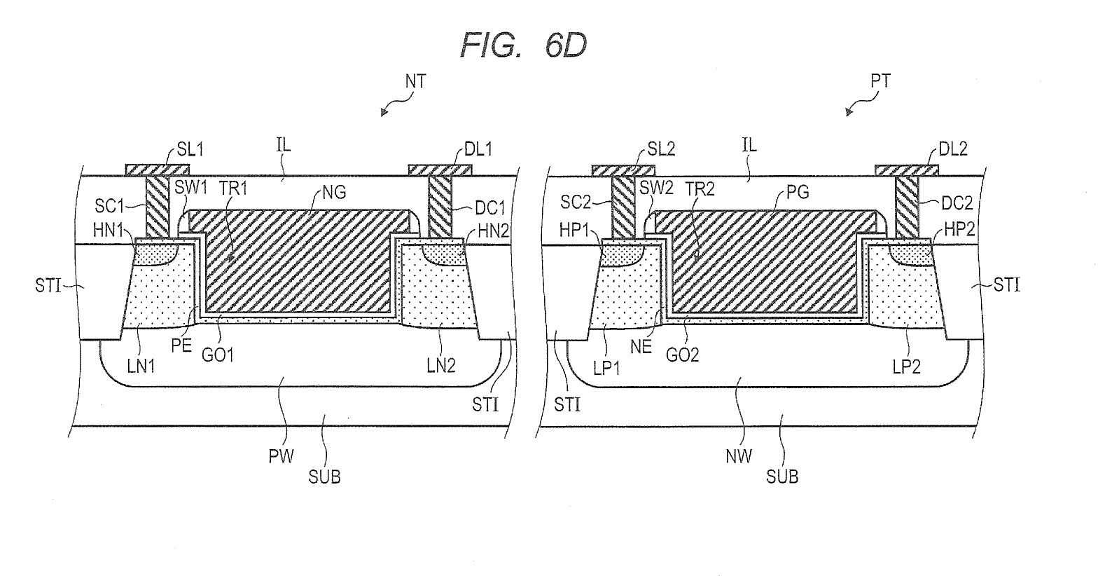

Then, a method of manufacturing the NMOS transistor NT and the PMOS transistor PT according to the first embodiment is to be described with reference to FIGS. 5A to 5H and FIGS. 6A to 6D. FIGS. 5A to 5H are cross sectional views explaining the method of manufacturing the NMOS transistor NT and the PMOS transistor PT according to the first embodiment, which correspond to the cross sectional view along the line IIc-IIc in FIG. 1 and the cross sectional view along the line IVc-IVc in FIG. 3. FIGS. 6A to 6D are cross sectional views explaining the method of manufacturing the NMOS transistor NT and the PMOS transistor PT according to the first embodiment, which correspond to the cross sectional view along the line IIa-IIa in FIG. 1 and the cross sectional view along the line IVa-IVa in FIG. 3.

First, as illustrated in FIG. 5A, a device isolation layer STI is formed to a predetermined position over the surface of a semiconductor substrate SUB. Then, a resist mask which is opened at a region for forming a well PW is formed over the semiconductor substrate SUB. Then, P-type impurities, for example, boron (B) are ion implanted over the entire surface of the semiconductor substrate SUB to form a well PW. After removing the resist mask for forming the well PW, a resist mask which is opened at a region for forming the well NW is formed over the semiconductor substrate SUB. Then, N-type impurities, for example, phosphorus (P) or arsenic (As) are ion implanted over the entire surface of the semiconductor substrate SUB to form a well NW. Subsequently, the resist mask for forming the well NW is removed.

The order of forming the wells PW and NW may be reversed. When a P-type semiconductor substrate is used as the semiconductor substrate SUB, only the well NW may be formed without forming the well PW. On the contrary, when an N-type semiconductor substrate is used as the semiconductor substrate SUB, only the well PW may be formed without forming the well NW.

Then, as illustrated in FIG. 5B, a masking insulating film IF1 comprising silicon oxide (SiO₂) of about 10 to 20 nm thickness and an insulating film IF2 comprising silicon nitride (Si₃N₄) of about 100 to 200 nm are formed over the entire surface of the semiconductor substrate SUB by, for example, a CVD (chemical vapor deposition) method. Further, a resist mask RL having opening for forming trenches TR1 and TR2 is formed over the insulating film IF2. Then, the insulating film IF1 and IF2 are removed by etching using the resist mask RL to expose the surface of the semiconductor substrate SUB. Further, plasma etching is applied to the semiconductor substrate SUB (wells PW, NW) using the resist mask RL as a mask to form trenches TR1 and TR2 in the semiconductor substrate SUB. Then, the resist mask RL is removed.

Alternatively, after removing the insulating films IF1 and IF2 in the opening by using the resist mask RL, the resist mask RL may be removed and the trenches TR1 and TR2 may be formed by using the insulating films IF1 and IF2 as a mask.

Then, as illustrated in FIG. 5C, after removing the insulating film IF1 and IF2 by etching, a masking insulating film IF3 comprising silicon oxide (SiO₂) of about 50 nm thickness is formed over the entire surface of the semiconductor substrate SUB (wells PW and NW, device isolation layer STI), for example, by a CVD method.

Then, as illustrated in FIG. 5D, a resist mask (not illustrated) is formed to a region for forming the PMOS transistor PT and the insulating film IF3 in the region for forming the NMOS transistor NT is removed. Then, a P-type epitaxial layer PE of about 50 to 100 nm thickness is formed over the well PW by a selective epitaxial growing method, for example, under the conditions in vacuum and at a temperature of 860 to 900° C. The P-type epitaxial layer PE is formed selectively only over the surface of the well PW but not formed over the surface of the device isolation layer ST1 and the insulating film IF3 over the region of forming the PMOS transistor PT.

Then, as illustrated in FIG. 5E, a masking insulating film IF4 comprising silicon oxide (SiO₂) of about 50 nm thickness is formed by, for example, a CVD method. Then, a resist mask (not illustrated) is formed to the region for forming the NMOS transistor NT, and the insulating films IF3 and IF4 in the region for forming the PMOS transistor PT are removed by etching. Then, the resist mask is removed.

Then, as illustrated in FIG. 5F, an N-type epitaxial layer NE of about 50 to 100 nm thickness is formed over the well NW under the conditions, for example, in vacuum and at a temperature of 860 to 900° C. by a selective epitaxial growing method. The N-type epitaxial layer NE is formed selectively only over the surface of the well NW but not formed over the surface of the device isolation layer STI and insulating film IF4 over the region for forming the NMOS transistor NT.

Then, as illustrated in FIG. 5G, the insulating film IF4 over the region for forming the NMOS transistor NT is removed by etching. Subsequently, gate oxide films GO1 and GO2 each of about 50 nm thickness are formed over the entire surface of the semiconductor substrate SUB by, for example, a CVD method. Then, an electroconductive film comprising, for example, polycrystal silicon to form gate electrodes NG and PG is formed to about 200 nm thickness over the entire surface of the semiconductor substrate SUB by a CVD method. Further, N-type impurities are ion implanted in the region for forming the NMOS transistor NT to form an N-type gate electrode NG by using a resist mask (not illustrated). Further, P-type impurities are ion implanted over the region for forming the PMOS transistor PT to form a P-type gate electrode PG. The N-type impurities and the P-type impurities can be about 1×10²⁰ to 1×10²¹ atoms/cm³, respectively.

Then as illustrated in FIG. 5H, the gate electrodes NG and PG are patterned each into a desired shape by dry etching using a resist mask.

Subsequent steps are to be described with reference to FIGS. 6A to 6D.

FIG. 6A is a cross sectional view along a different cross section in the identical manufacturing step with that in FIG. 5H. The source low impurity concentration regions LN1 and LP1 and the drain low impurity concentration regions LN2 and LP2 illustrated in FIG. 6A are formed after forming the wells PW and NW (FIG. 5A) and before forming the trenches TR1 and TR2 (FIG. 5B). Before explaining the steps illustrated at and after FIG. 6B, steps of forming the source low impurity concentration regions LN1 and LP1 and the drain low impurity concentration regions LN2 and LP2 are to be described below.

A resist mask which is opened at the region for forming the source low impurity concentration region LN1 and the drain low impurity concentration region LN2 is formed over the entire surface of the semiconductor substrate SUB. Then, N-type impurities, for example, phosphorus (P) or arsenic (As) are ion implanted over the entire surface of the semiconductor substrate SUB using the resist mask as a mask to form the source low impurity concentration region LN1 and the drain low impurity concentration region LN2.

After once removing the resist mask, a resist mask which is opened at a region for forming the source low impurity concentration region LP1 and the drain low impurity concentration region LP2 is formed over the entire surface of the semiconductor substrate SUB. Then, P-type impurities, for example, boron (B) are ion implanted over the entire surface of the semiconductor substrate SUB using the resist mask as a mask to form the source low impurity concentration region LP1 and the drain low impurity concentration region LP2. Then, the resist mask is removed. The order of ion implanting the N-type impurities and the P-type impurities may be reversed. The shape of the opening of the resist mask and the conditions for ion implantation are properly determined considering the diffusion amount of the impurities.

Then, the N-type impurities in the source low impurity concentration region LN1 and the drain low impurity concentration region LN2, and the P-type impurities in the source low impurity concentration region LP1 and the drain low impurity concentration region LP2 are diffused by a heat treatment.

Then, steps after patterning the gate electrodes NG and PG illustrated in FIG. 5H and FIG. 6A are to be described.

As illustrated in FIG. 6B, the side walls SW1 and SW2 are formed on the lateral surfaces of the gate electrodes NG and PG that protrude from the semiconductor substrate SUB (gate oxide films GO1 and GO2) are formed. The side walls SW1 and SW2 can be formed by an insulating film such as an oxide film or a nitride film. For example, after growing the insulating film by a CVD method, the insulating film for the planar portion is entirely removed by anisotropic dry etching, for example, an RIE (Reactive Ion Etching) method to leave the insulating film only on the lateral surface of the gate electrode NG, whereby the side walls SW1 and SW2 can be formed. In this step, unnecessary portions of the gate oxide films GO1 and GO2 (regions not covered by the gate electrodes NG, PG) are removed simultaneously.

Then, as illustrated in FIG. 6C, a resist mask (not illustrated) is formed to a region for forming the PMOS transistor PT and N-type impurities such as phosphorus (P) or arsenic (As) are ion implanted over the entire surface of the semiconductor substrate to form the source high impurity concentration region HN1 and the drain high impurity concentration region HN2. In this step, the gate electrode NG and the side walls SW1 serve as a mask.

After once removing the resist mask, a resist mask (not illustrated) is formed over a region for forming the NMOS transistor NT, and P-type impurities, for example, boron (B) are ion implanted over the entire surface of the semiconductor substrate SUB to form a source high impurity concentration region HP1 and a drain high impurity concentration region HP2. In this step, the gate electrode PG and the side walls SW2 serve as a mask. The order of implanting ions of the N-type impurities and the P-type impurities may be reversed.

Successively, impurities in the source high impurity concentration regions HN1 and HP1 and the drain high impurity concentration regions HN2 and HP2 are diffused by, for example, an RTA (Rapid Thermal Annealing) method at 1000° C. for 30 sec. When the source and drain high impurity concentration regions HN1 and HN2 are formed the epitaxial layer PE present over the regions have a conduction type identical with that of the source and drain high impurity concentration regions HN1 and HN2. Further, when the source and the drain high impurity concentration regions HP1 and HP2 are formed, the epitaxial NE present over the regions have a conduction type identical with that of the drain high impurity concentration regions HP1 and HP2.

Finally, as illustrated in FIG. 6D, an interlayer insulating film IL is formed over the semiconductor substrate SUB in which the gate electrodes NG and the PG are formed. Then, after forming contact holes reaching the epitaxial layers PE and NE in the interlayer insulating film IL, the contact holes are filled with a metal such as tungsten (W) to form source contacts SC1 and SC2, and drain contacts DC1 and DC2. Source interconnects SL1 and SL2 comprising, for example, aluminum (Al) are formed over the source contacts SC1 and SC2, respectively. Further, drain interconnects DL1 and DL2 comprising, for example, aluminum (Al) are formed over the drain contacts DC1 and DC2 respectively. Thus, the NMOS transistor NT and the PMOS transistor PT according to the first embodiment are obtained.

As has been described above, since the NMOS transistor NT and the PMOS transistor PT according to the first embodiment have epitaxial layers PE and NE of uniform impurity concentration that serve as a channel region on the lateral surfaces of the trenches TR1 and TR2, a threshold voltage of the transistors can be easily set to a desired value.

### Second Embodiment

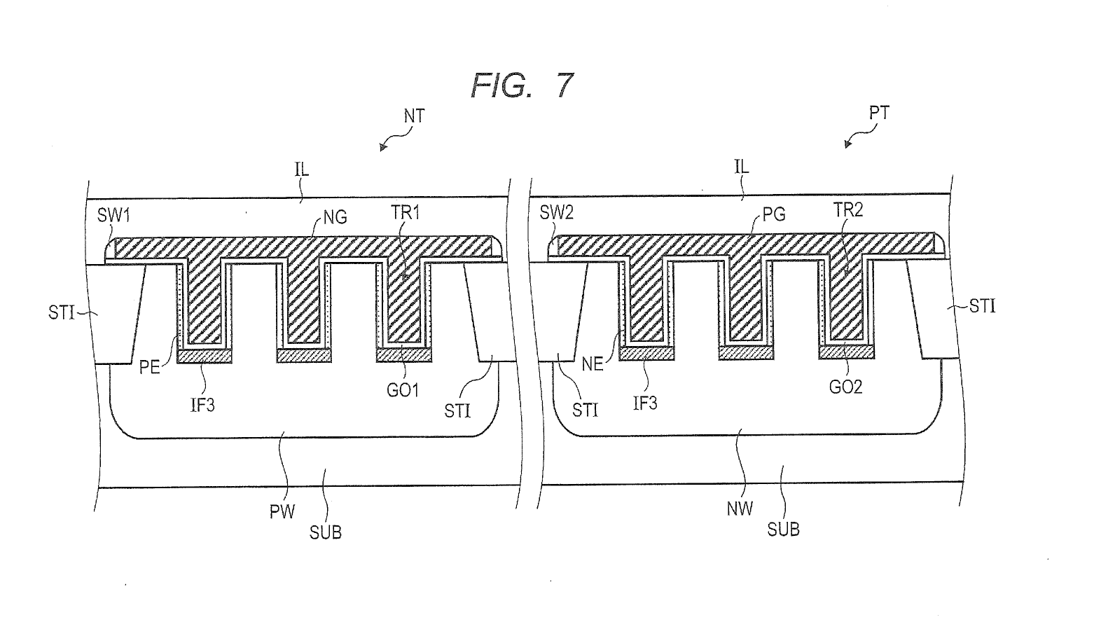

Then, transistors according to a second embodiment are to be described with reference to FIG. 7. FIG. 7 is a cross sectional view of an NMOS transistor NT and a PMOS transistor PT according to the second embodiment. FIG. 7 corresponds to the cross sectional view along the line IIa-IIa in FIG. 1 and the cross sectional view along the line IVa-IVa in FIG. 3.

As illustrated in FIG. 7, in the NMOS transistor NT according to the second embodiment, an epitaxial layer PE is formed only on the lateral surfaces and the end surfaces (not illustrated) of the trenches TR1 but is not formed over the bottom of the trenches TR1 and the surface of the well PW. Further, an insulating film IF3 is formed over the bottom of the trenches TR1. The insulating film IF3 comprises, for example, silicon oxide (SiO₂) of 50 to 150 nm, preferably, about 100 nm.

In the same manner, in the PMOS transistor PT, an epitaxial layer NE is formed only on the lateral surfaces and the end surfaces (not illustrated) of the trenches TR2 but is not formed over the bottom of the trenches TR2 and the surface of the well PW. Further, an insulating film IF3 identical with that of the NMOS transistor NT is formed also over the bottom of the trench TR2.

Since other configurations are identical with those of the NMOS transistor NT and the PMOS transistor PT according to the first embodiment, description therefor is to be omitted.

In the PMOS transistor NT and the PMOS transistor PT according to the first embodiment, the epitaxial layers PE and NE are formed over the entire inner surface of the trenches TR1 and TR2 (lateral surfaces, end surfaces, bottoms). In this case, crystal defects or defective shape such as constriction caused by stress may possibly occur at the corners of the bottom of the trenches TR1 and TR2 (crossing portion between the bottom and the lateral surface or the end surface) during epitaxial growing. Due to the defective shape, leak current, etc. may possibly occur to deteriorate the characteristics of the transistor.

On the contrary, in the NMOS transistor NT and the PMOS transistor PT according to the second embodiment, since the epitaxial layers PE and NE are not formed over the bottom of the trenches TR1 and TR2, there is no possibility of generating crystal defects or defective shape in the epitaxial layers PE and NE. In addition, since the epitaxial layers PE and NE of uniform impurity concentration that serve as the channel region are provided on the lateral surfaces of the trenches TR1 and TR2 in the same manner as in the first embodiment, a threshold voltage of the transistor can be easily set to a desired value. Further, since the insulating film IF3 is formed over the bottom of the trenches TR1 and TR2, if a gate voltage is applied, the channel region is not formed below the bottom of the trenches TR1 and TR2.

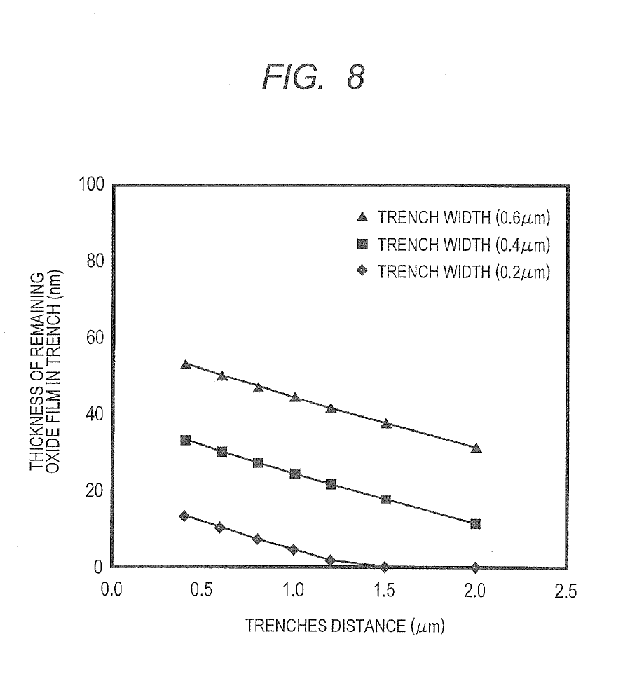

The insulating film IF3 in FIG. 7 is formed by filling the inside of the trenches TR1 and TR2 with the insulating film and then etching the insulating film thereby leaving the film only over the bottom of the trenches TR1 and TR2. FIG. 8 is a graph showing the dependence, on the trench distance, of the thickness of the insulating film IF3 remaining in the inside of the trenches TR1 and TR2 (thickness of the oxide film left in the trench). The abscissa represents the trench distance and the ordinate represents the thickness of the oxide film left in the trench. Rhombic symbols show a case of trench width=0.2 μm, square symbols show a case of trench width=0.4 μm, and trigonal symbols shows a case of trench width=0.6 μm. As illustrated in FIG. 8, the thickness of the oxide film left in the trench is decreased as the trench width is smaller or the trench distance is larger. Accordingly, for making the thickness of the insulating film IF3 remaining inside of the trenches TR1 and TR2 uniform, it is preferred that the trench distance and the trench width are set constant.

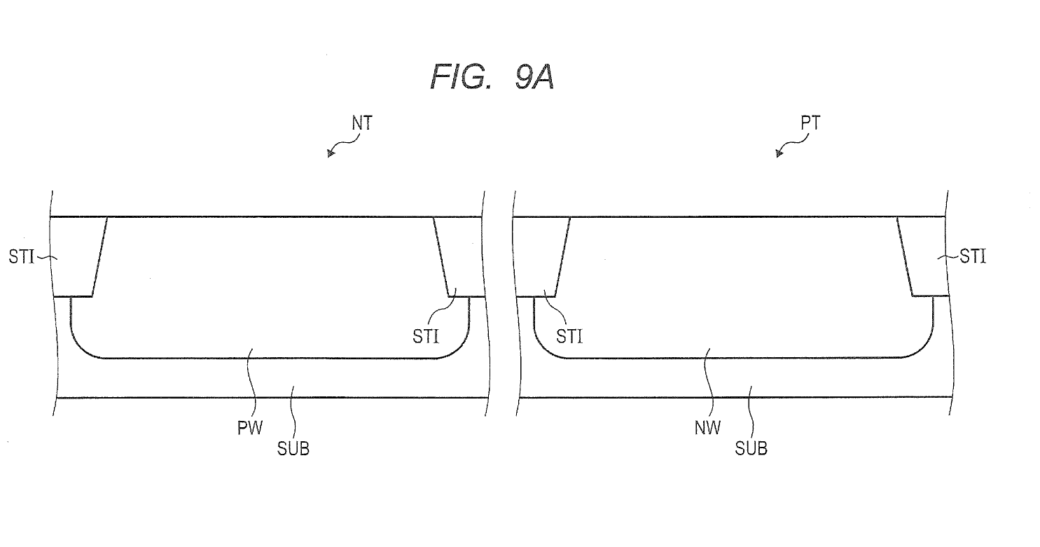

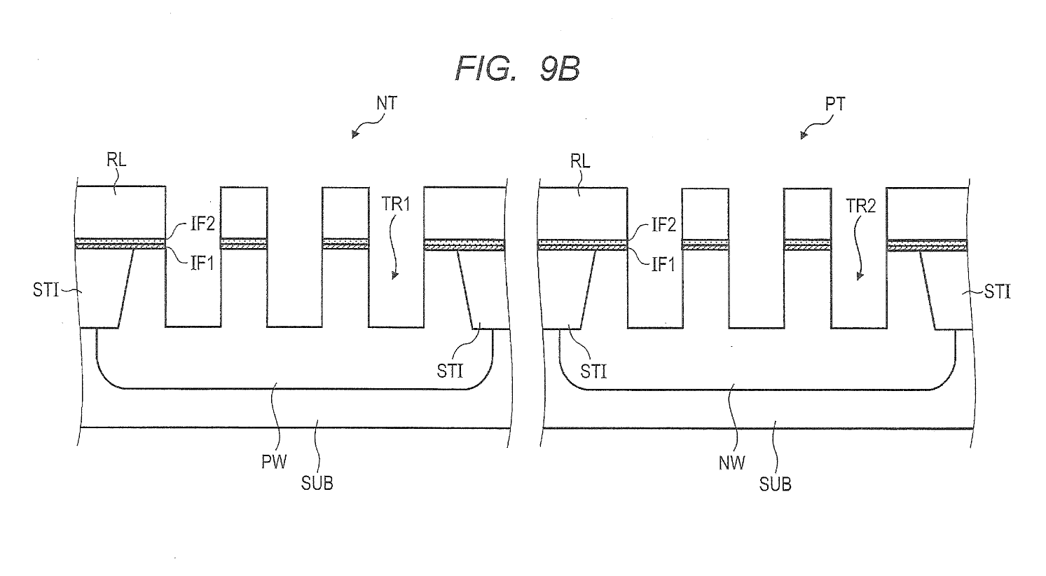

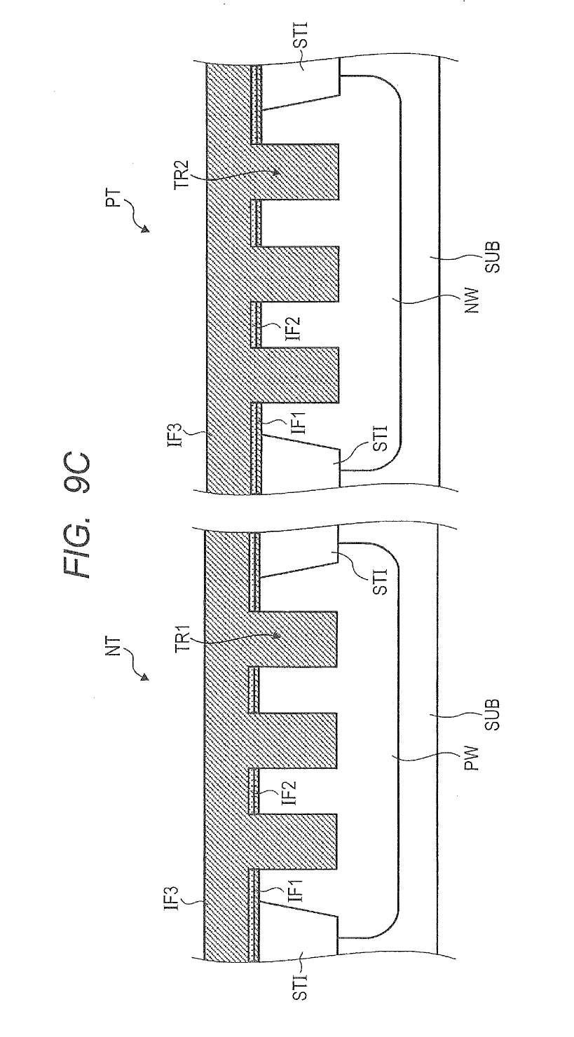

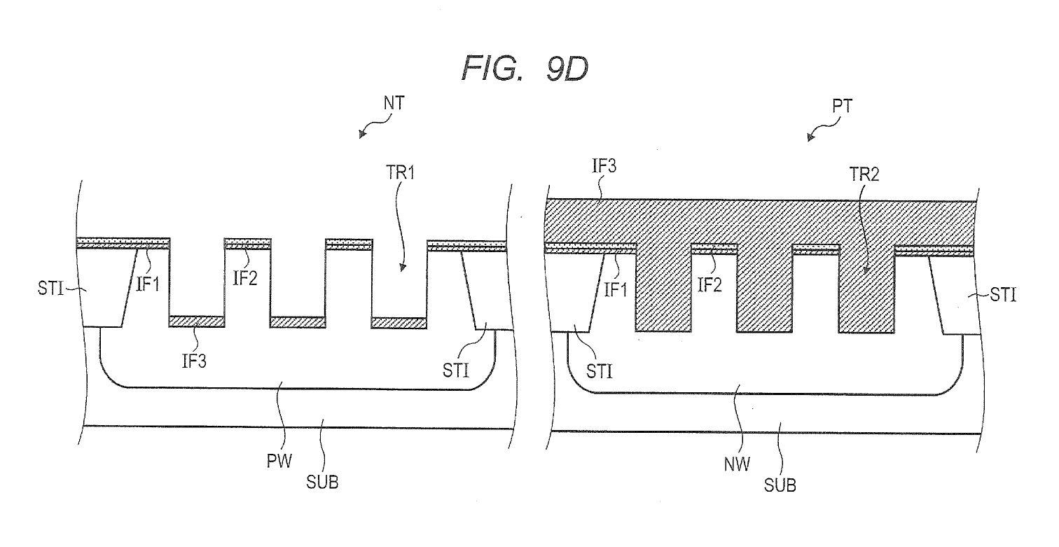

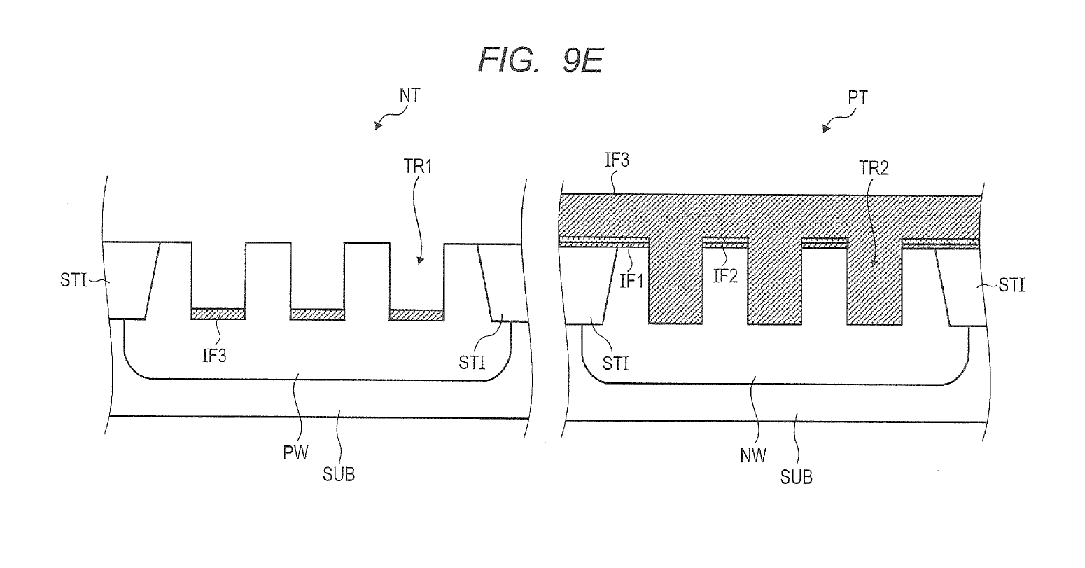

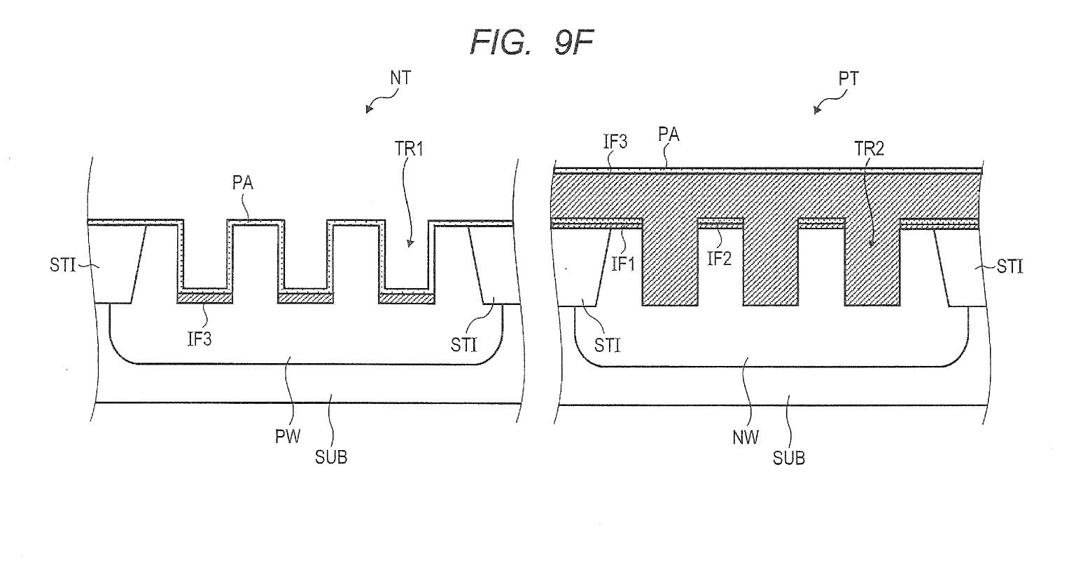

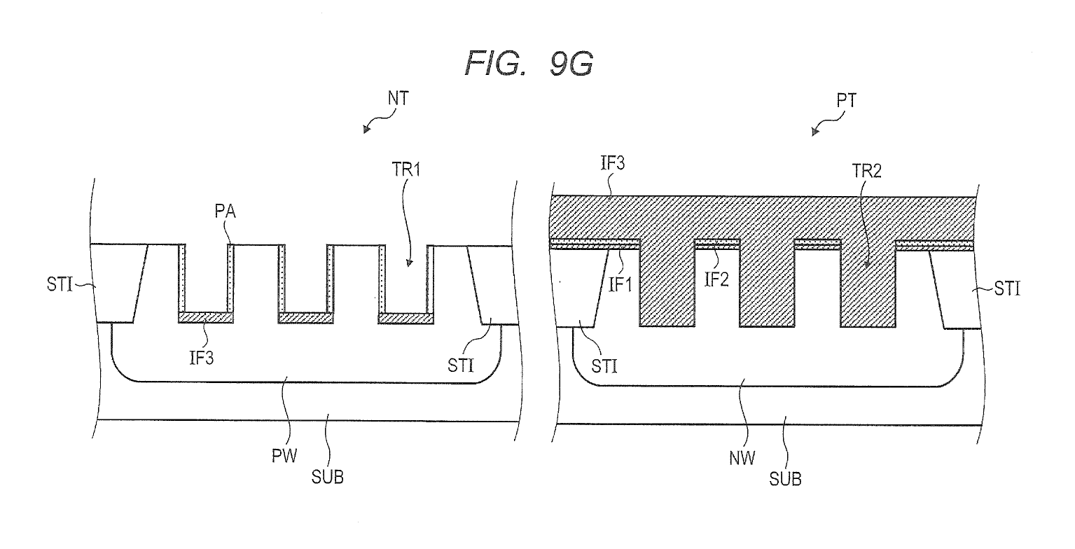

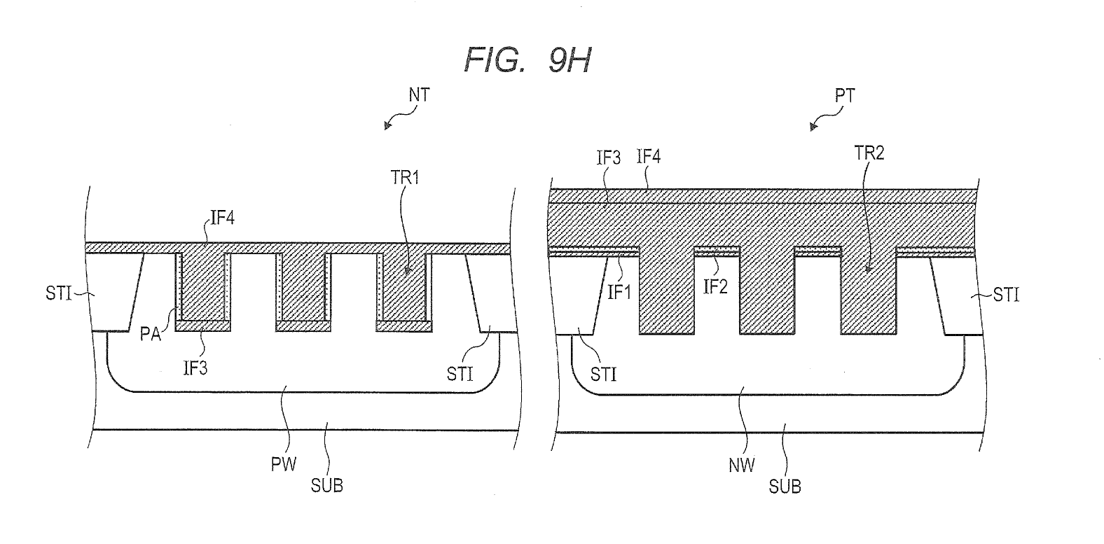

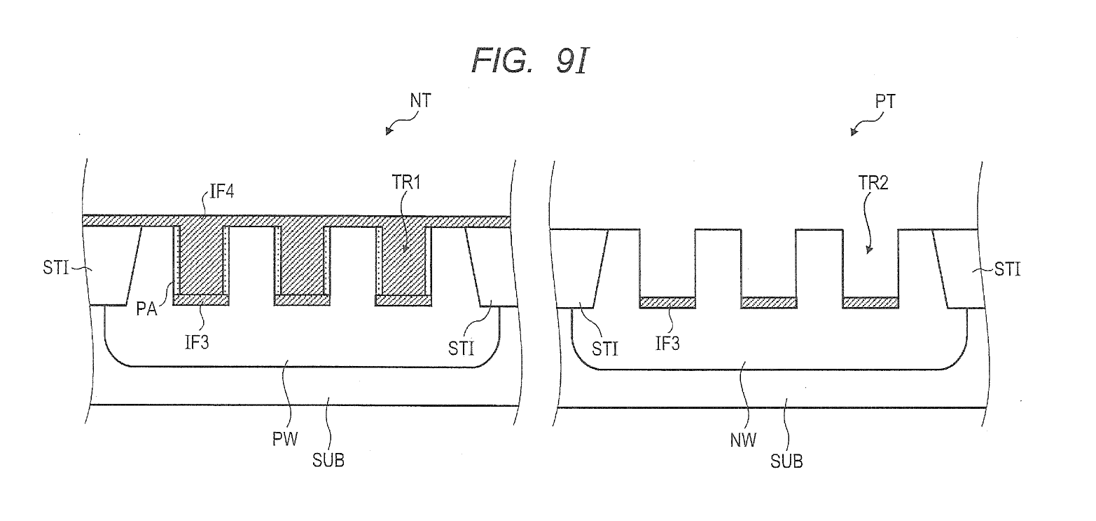

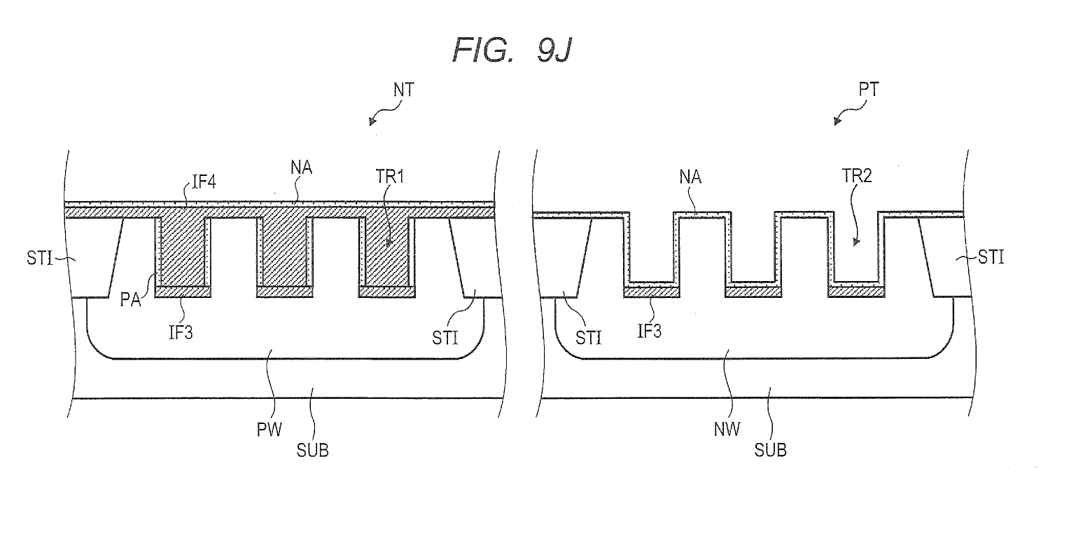

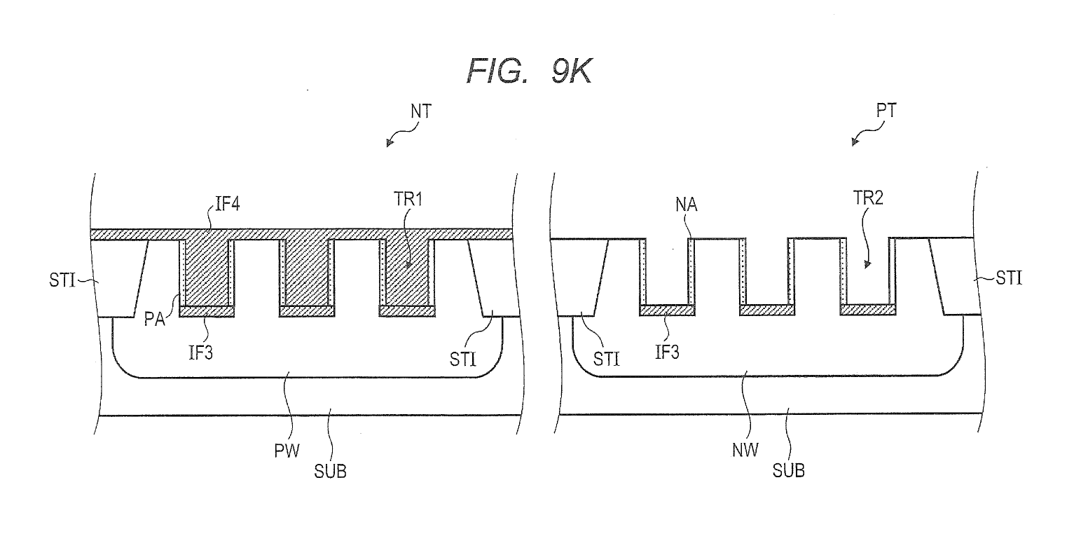

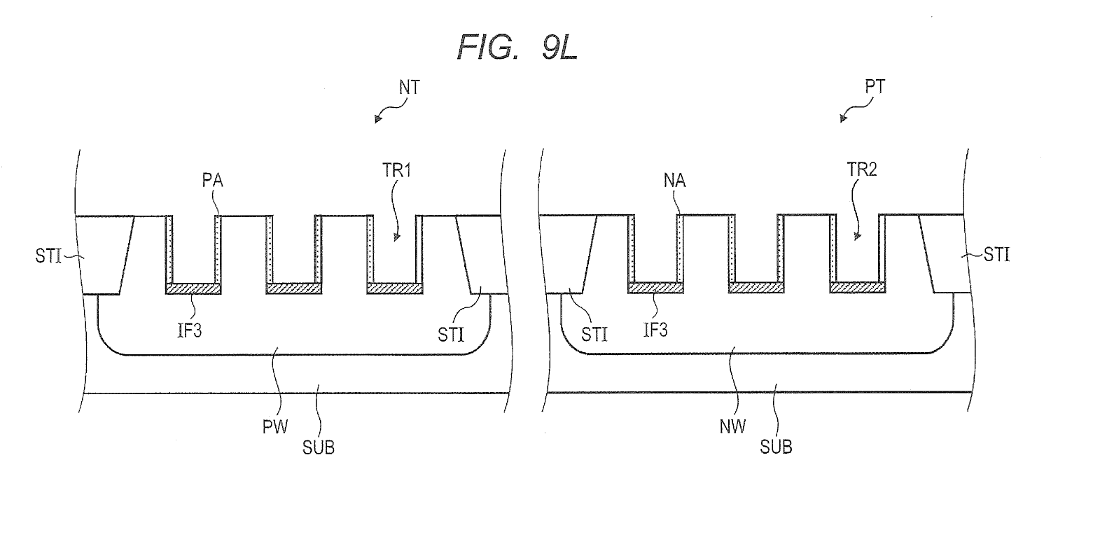

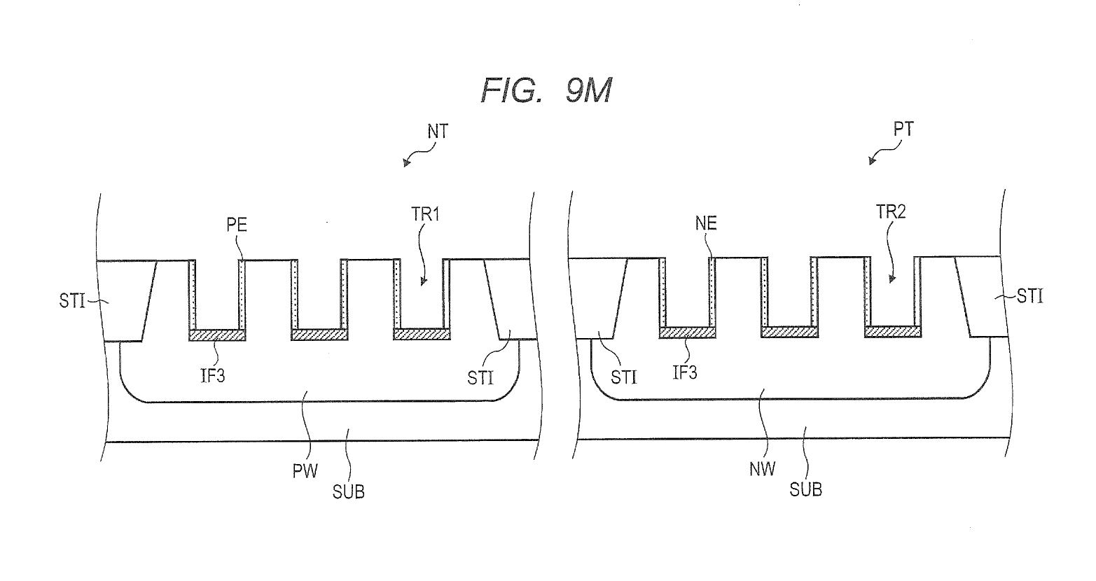

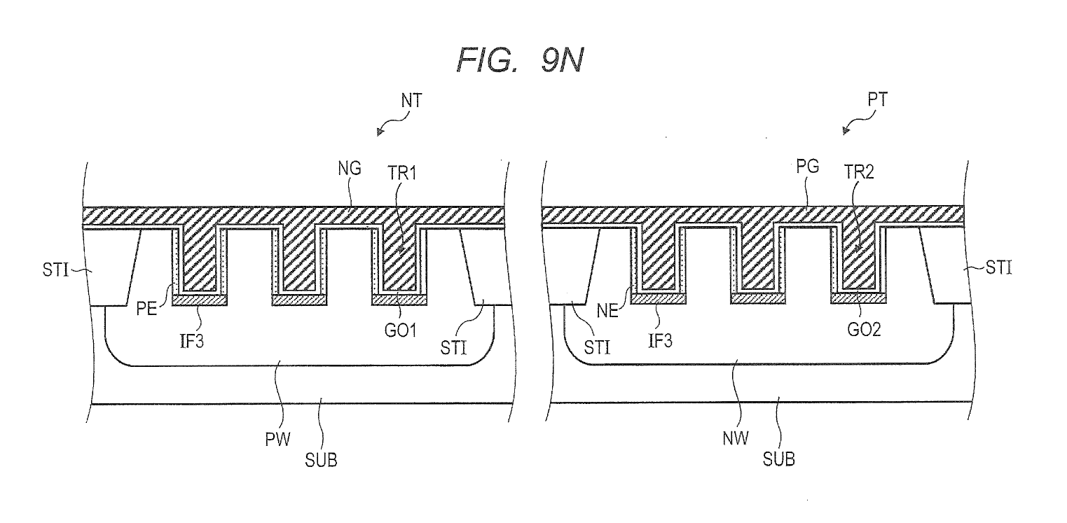

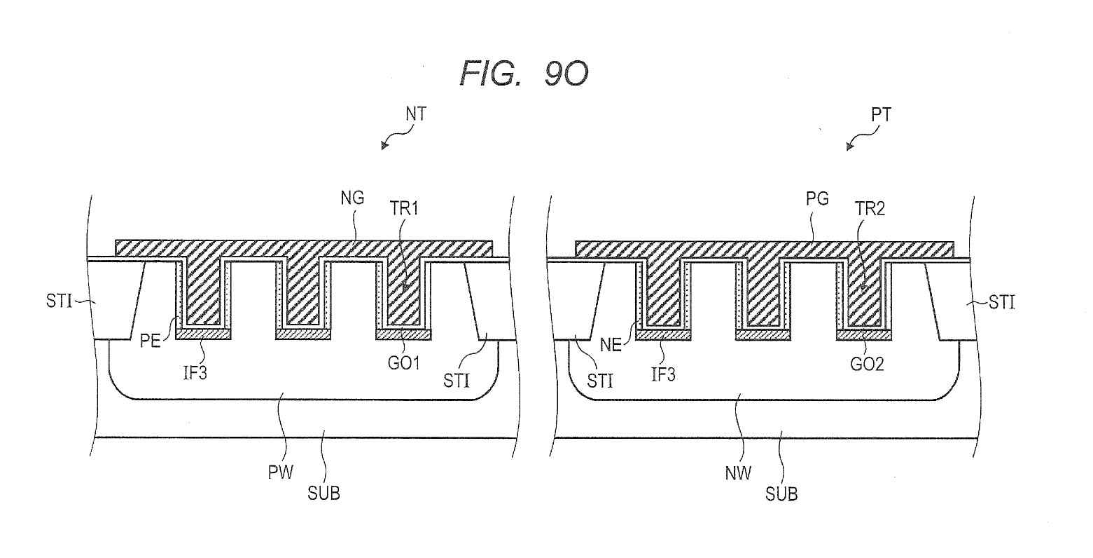

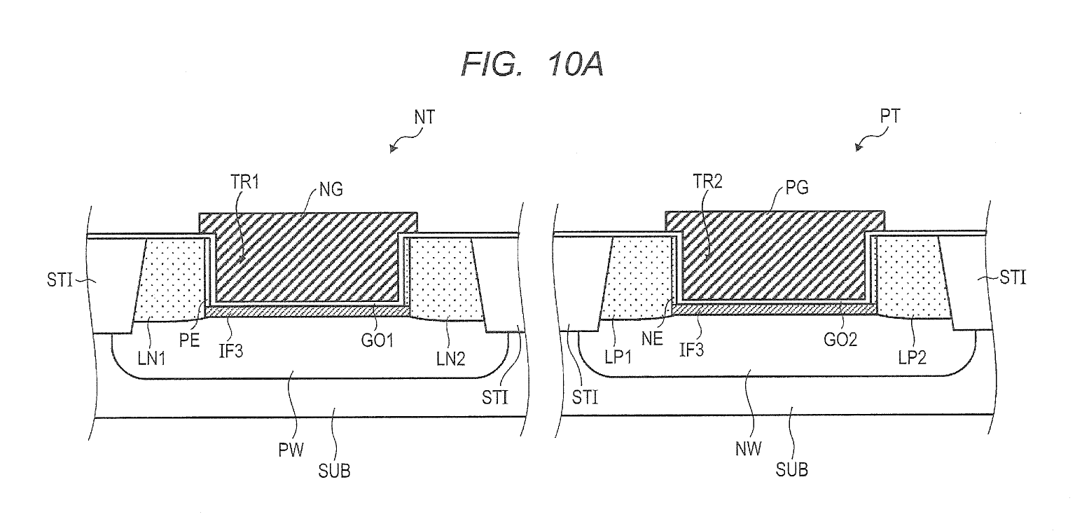

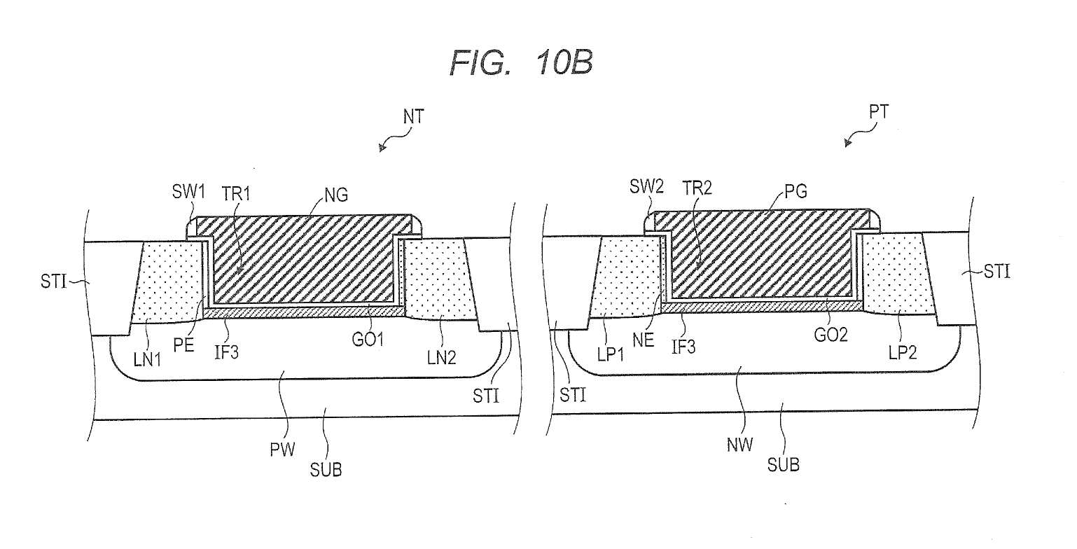

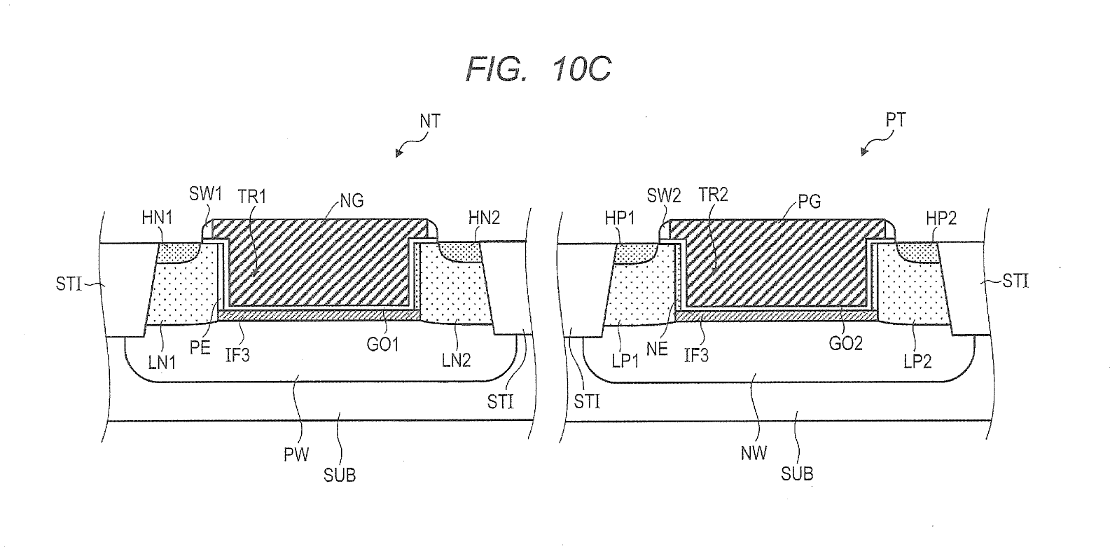

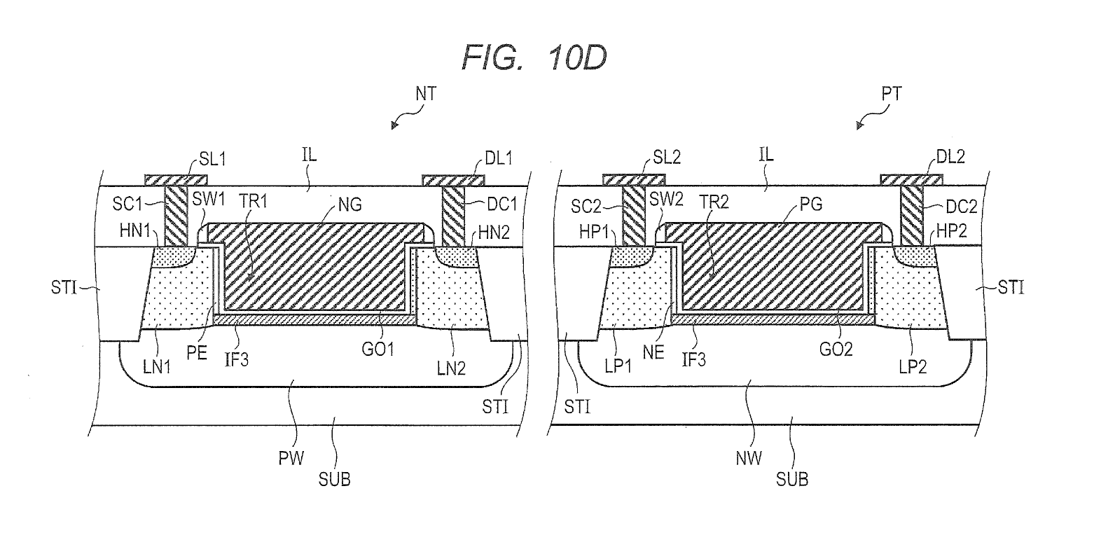

Then, a method of manufacturing the NMOS transistor NT and the PMOS transistor PT according to the second embodiment is to be described with reference to FIGS. 9A to 9O and 10A to 10D. FIGS. 9A to 9O are cross sectional views explaining a method of manufacturing the NMOS transistor NT and the PMOS transistor PT according to the second embodiment, which correspond to the cross sectional view along the line IIc-IIc in FIG. 1 and the cross sectional view along the line IVc-IVc in FIG. 3. FIGS. 10A to 10D are cross sectional views explaining a method of manufacturing the NMOS transistor NT and the PMOS transistor PT according to the second embodiment, which correspond to the cross sectional view along the line IIa-IIa in FIG. 1 and the cross sectional view along the line IVa-IVa in FIG. 3.

Since FIGS. 9A and 9B are in common with FIGS. 5A and 5B according to the first embodiment and the manufacturing steps are also identical, description therefor is to be omitted.

Then, as illustrated in FIG. 9C, an insulating film IF3 is formed by, for example, a CVD method over the entire surface of a semiconductor substrate SUB (wells PW and NW, device isolation layer STI) formed with trenches TR1 and TR2 while leaving insulating films IF1 and IF2 to fill the inside of the trenches TR1 and TR2 by the insulating film IF3.

Then, as illustrated in FIG. 9D, a resist mask (not illustrated) is formed over a region for forming the PMOS transistor PT and the insulating film IF3 in a region for forming the NMOS transistor NT is removed by etching using the insulating films IF1 and IF2 as a mask. In this step, the insulation film IF3 is left by about 100 nm over the bottom of the trenches TR1 as described above. Then, the resist mask (not illustrated) is removed.

Then, as shown in FIG. 9E, the insulating films IF1 and IF2 in the region for forming the NMOS transistor NT are removed.

Then, as illustrated in FIG. 9F, a P-type amorphous silicon layer PA, for example, of about 50 to 100 nm thickness is formed over the entire surface of the semiconductor substrate SUB by, for example, a CVD method.

Then, as illustrated in FIG. 9G, the P-type amorphous silicon film PA over the surface of the semiconductor substrate SUB and the bottom of the trenches TR1 is removed by etching back. Thus, the P-type amorphous silicon layer PA remains only on the lateral surfaces and the end surfaces of the trenches TR1.

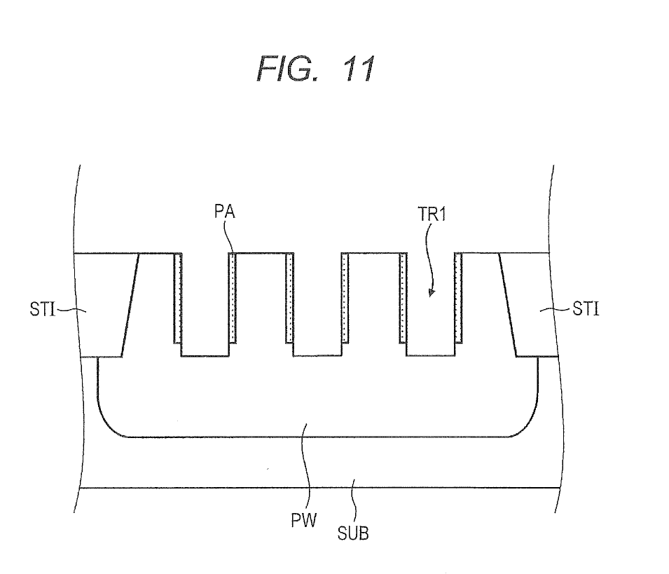

FIG. 11 is a view explaining the effect of the insulating film IF3 formed over the bottom of the trenches TR1. If the insulating film IF3 does not remain over the bottom of the trench TR1, the semiconductor layer over the bottom (well PW) is engraved downwardly upon etching back of the amorphous layer PA to cause variation in the depth of the trenches TR1. The situation is identical also for the trenches TR2.

Then, as illustrated in FIG. 9H, a masking insulating film IF4 comprising silicon oxide (SiO₂) is formed over the entire surface of the semiconductor substrate SUB by, for example, a CVD method, to fill the inside of the trenches TR1 with the insulating film IF4.

Then, as illustrated in FIG. 9I, a resist mask (not illustrated) is formed in a region for forming the NMOS transistor NT and the insulating films IF3 and IF4 in the region for forming the PMOS transistor PT are removed by wet etching. In this step, the insulating film IF3 is left by about 100 nm over the bottom of the trenches TR2. Then, the resist mask (not illustrated) is removed.

Then, as illustrated in FIG. 9J, an N-type amorphous silicon layer NA, for example, of about 50 to 100 nm thickness is formed over the entire surface of the semiconductor substrate SUB by, for example, a CVD method.

Then as illustrated in FIG. 9K, the N-type amorphous silicon layer NA over the surface of the semiconductor substrate SUB and the bottom of the trenches TR2 are removed by etching back. Thus, the N-type amorphous silicon layer NA is left only on the lateral surfaces and the end surfaces of the trenches TR2.

Then, as illustrated in FIG. 9L, the insulating film IF4 over the region for forming the NMOS transistor NT is removed by etching.

Then, as illustrated in FIG. 9M, the P-type amorphous silicon layer PA and the N-type amorphous silicon layer NA are epitaxialized under the conditions, for example, in vacuum, at a temperature of 600° C., for one hour to form epitaxial layers PE and NE.

Then, as illustrated in FIG. 9N, gate oxide films GO1 and GO2, and gate electrodes NG and PG are formed over the entire surface of the semiconductor substrate SUB in the same manner as in the first embodiment.

Then, as illustrated in FIG. 9O, the gate electrodes NG and PG are patterned each into a desired shape by dry etching using a resist mask.

Subsequent steps are to be described with reference to FIGS. 10A to 10D.

FIG. 10A is a cross sectional view at a different cross section in the manufacturing step identical with that in FIG. 9O. FIG. 9O corresponds to the cross sectional view along the line IIc-IIc in FIG. 1 and the cross sectional view along the line IVc-IVc in FIG. 3, whereas FIG. 10A corresponds to the cross sectional view along the line IIa-IIa in FIG. 1 and the cross sectional view along the line IVa-IVa in FIG. 3.

Source low impurity concentration regions LN1 and NP1 and drain low impurity concentration regions LN2 and LP2 illustrated in FIG. 10A are formed after forming the wells PW and NW (FIG. 10A) and before forming the trenches TR1 and 1R2 (FIG. 10B) in the same manner as in the first embodiment. Since the steps of forming the source low impurity concentration regions LN1 and LP1 and the drain low impurity concentration regions LN2 and LP2 are identical with those in the first embodiment, description therefor is to be omitted.

Then, steps after patterning the gate electrodes NG and PG illustrated in FIG. 9O and FIG. 10A are to be described.

As illustrated in FIG. 10B, side walls SW1 and SW2 are formed and unnecessary portions of the gate oxide films GO1 and GO2 are removed in the same manner as in the first embodiment.

Then, as illustrated in FIG. 10C, source high impurity concentration regions HN1 and HP1 and drain high impurity concentration regions HN2 and HP2 are formed in the same manner as in the first embodiment.

Finally, as illustrated in FIG. 10D, after forming an interlayer insulating film IL over the semiconductor substrate SUB in which the gate electrodes NG and the PG have been formed. Then, after forming contact holes reaching the source high impurity concentration regions HN1 and HP1 and drain high impurity concentration regions HN2 and HP2 in the interlayer insulating film IL, the contact holes are filled with a metal such as tungsten (W) to form source contacts SC1 and SC2, and drain contacts DC1 and DC2. Source interconnects SL1 and SL2 comprising, for example, aluminum (Al) are formed over the source contacts SC1 and SC2, respectively. Further, drain interconnects DL1 and DL2 comprising, for example, aluminum (Al) are formed over the drain contacts DC1 and DC2 respectively. Thus, the NMOS transistor NT and the PMOS transistor PT according to the second embodiment are obtained.

As described above, in the NMOS transistor NT and the PMOS transistor PT according to the second embodiment, since the epitaxial layers PE and NE are not formed over the bottom of the trenches TR1 and TR2, there is no possibility of resulting crystal defect or defective shape in the epitaxial layers PE and NE. In addition, since the epitaxial layers PE and NE of uniform impurity concentration that serve as channel regions are provided on the lateral surfaces of the trenches TR1 and TR2, a threshold voltage of the transistor can be easily set to a desired value in the same manner as in the first embodiment.

### Third Embodiment

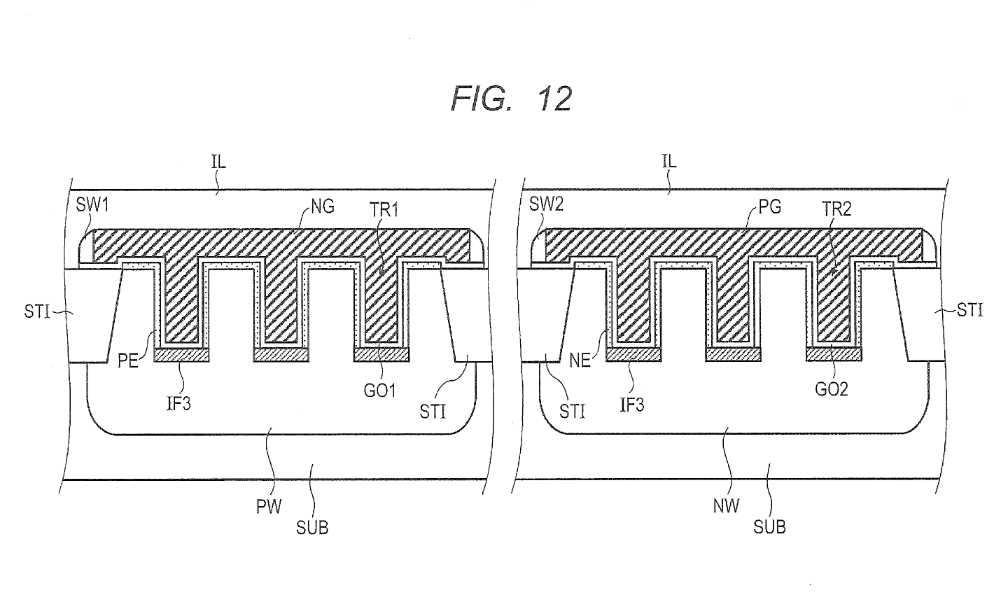

Then, transistors according to a third embodiment are to be described with reference to FIG. 12. FIG. 12 is a cross sectional view of an NMOS transistor NT and a PMOS transistor PT according to the third embodiment. FIG. 12 corresponds to the cross sectional view along the line IIa-IIa in FIG. 1 and the cross sectional view along the line IVa-IVa in FIG. 3.

As illustrated in FIG. 12, in the NMOS transistor NT according to the third embodiment, the epitaxial layer PE is formed over the surface of the well PW, the lateral surfaces and the end surfaces (not illustrated) of trenches TR1 and is not formed over the bottom of the trenches TR1. Further, an insulating film IF3 identical with that of the second embodiment is formed over the bottom of the trenches TR1.

In the same manner, in the PMOS transistor PT according to the third embodiment, the epitaxial layer NE is formed over the surface of the well PW, the lateral surfaces and the end surface (not illustrated) of trenches TR2 and is not formed over the bottom of the trenches TR2. Further, an insulating film IF3 identical with that of the NMOS transistor NT is formed also over the bottom of the trenches TR2.

Since other configurations are identical with those of the NMOS transistor NT and the PMOS transistor PT according to the first embodiment, description therefor is to be omitted.

In the NMOS transistor NT and the PMOS transistor PT according to the third embodiment, since the epitaxial layers PE and NE are not formed over the bottom of the trenches TR1 and TR2 in the same manner as in the second embodiment, there is no possibility of resulting crystal defect or defective shape to the epitaxial layers PE and NE. In addition, since the epitaxial layers PE and NE of uniform impurity concentration that serve as channel regions are provided on the lateral surface of the trenches TR1 and TR2 in the same manner as in the first embodiment, a threshold voltage of the transistor can be easily set to a desired value. Further, since the insulating film IF3 is formed over the bottom of the trenches TR1 and TR2 in the same manner as in the second embodiment, the channel regions are not formed below the bottom of the trenches TR1 and TR2 even when a gate voltage is applied.

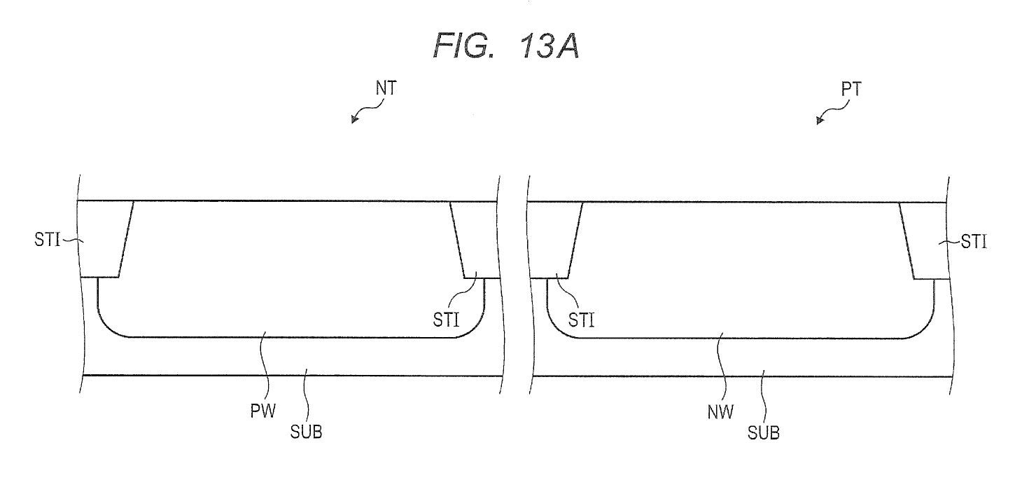

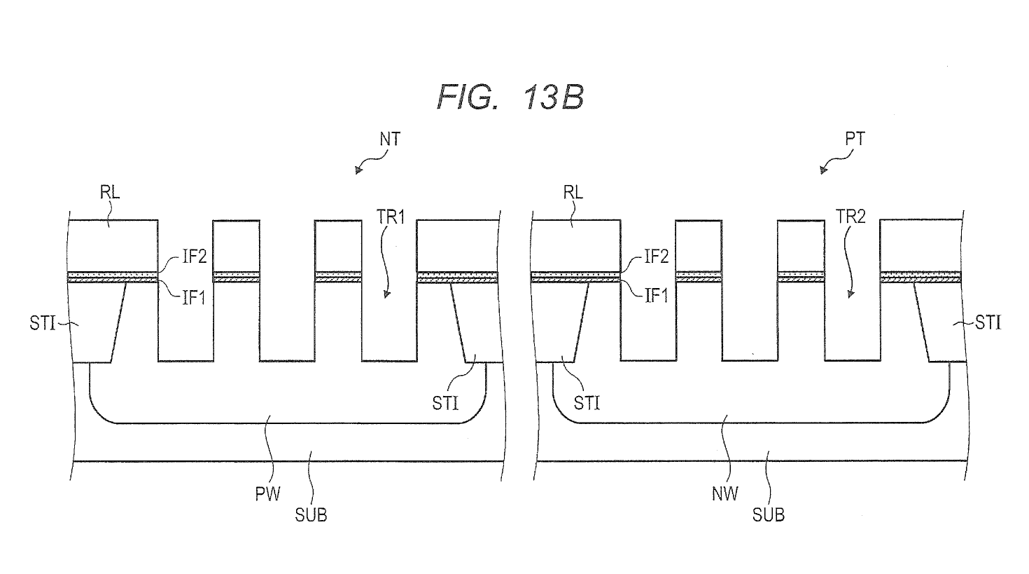

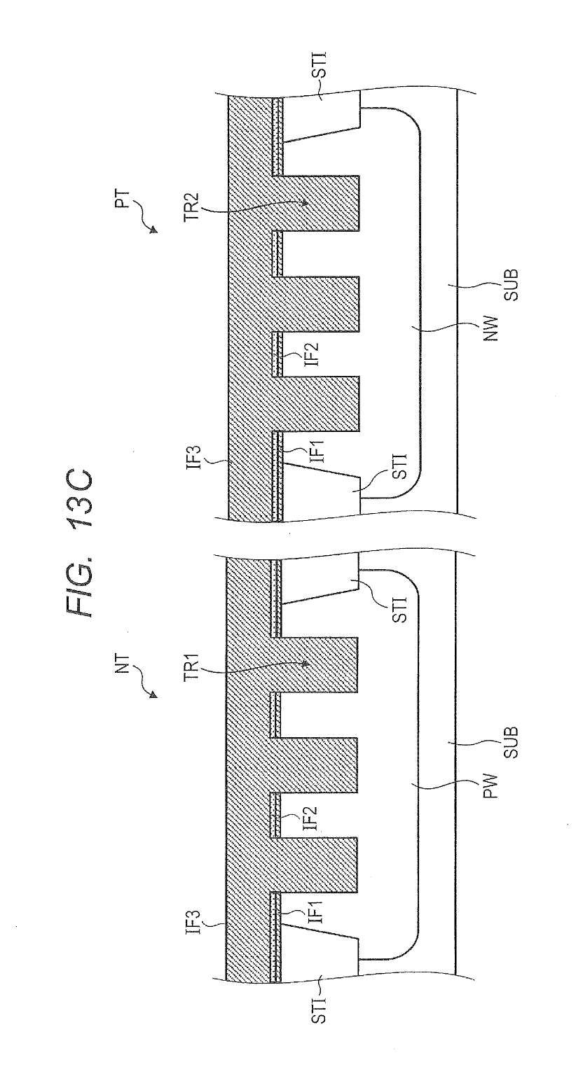

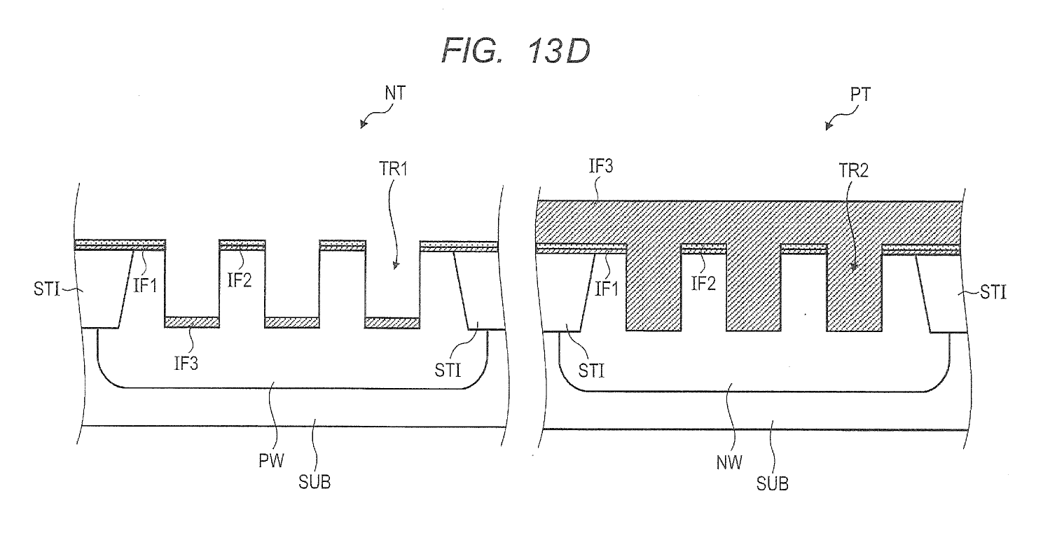

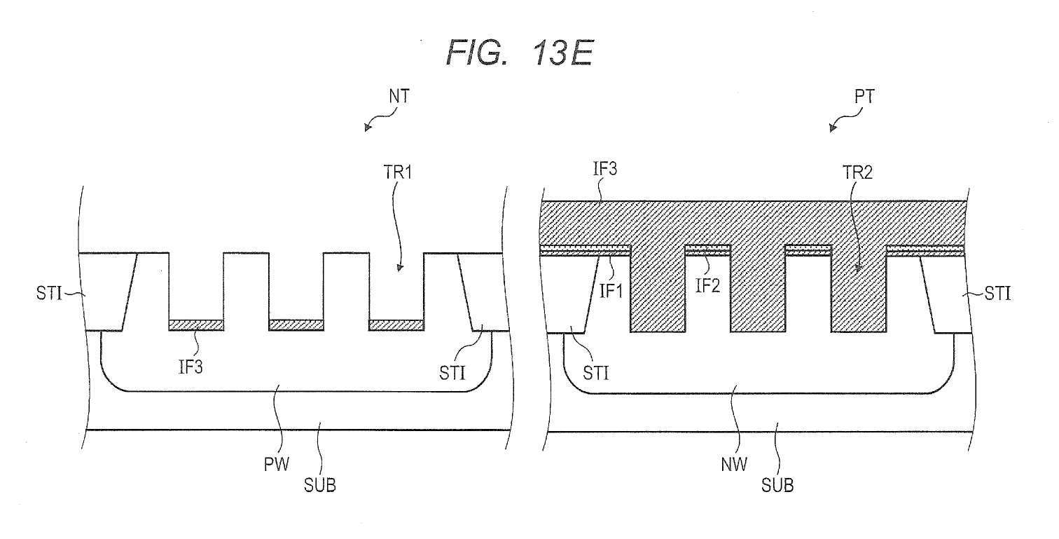

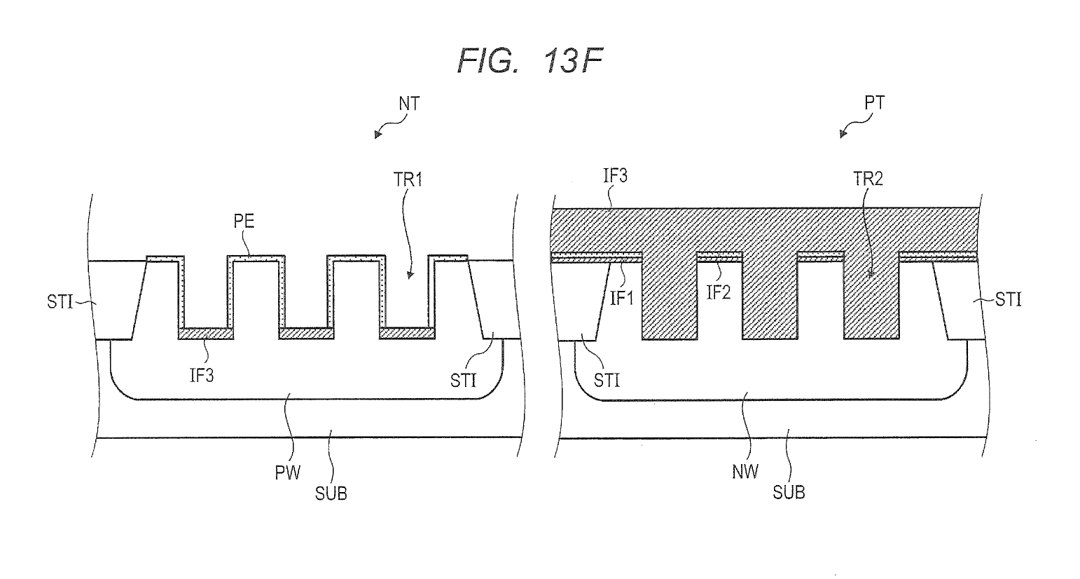

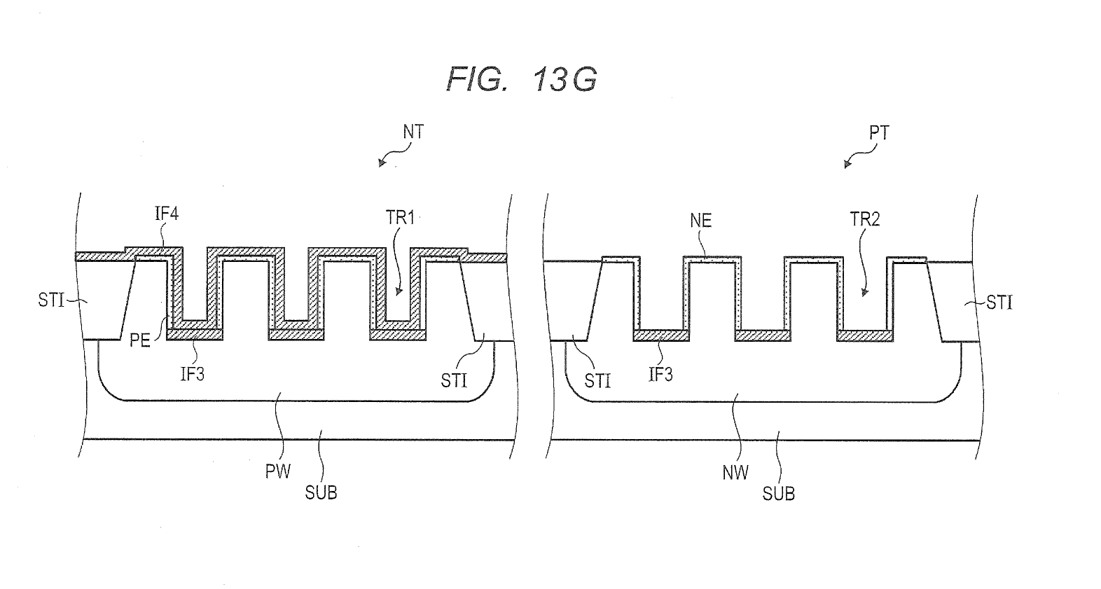

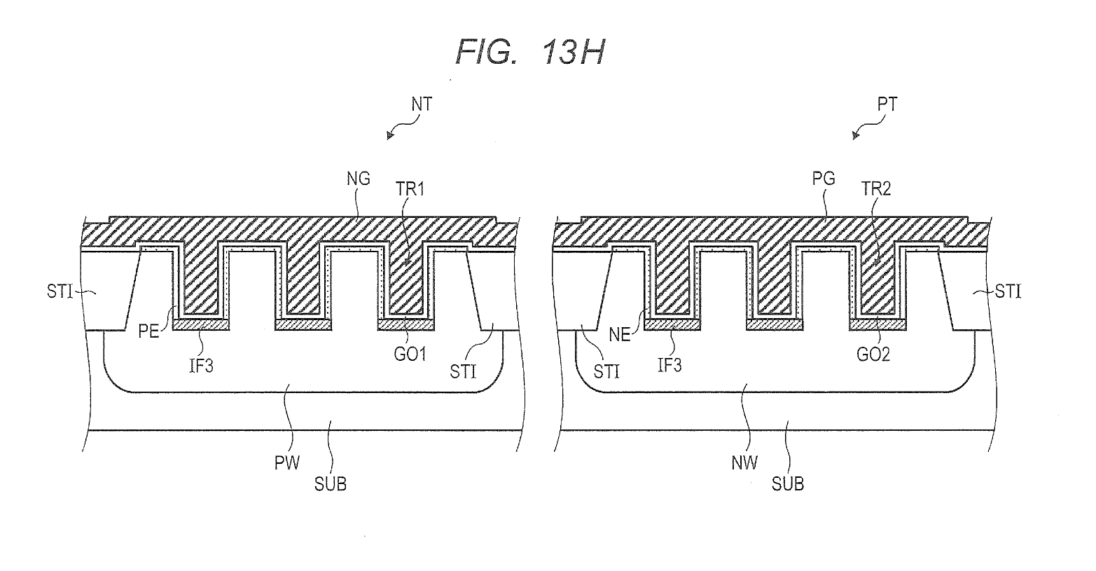

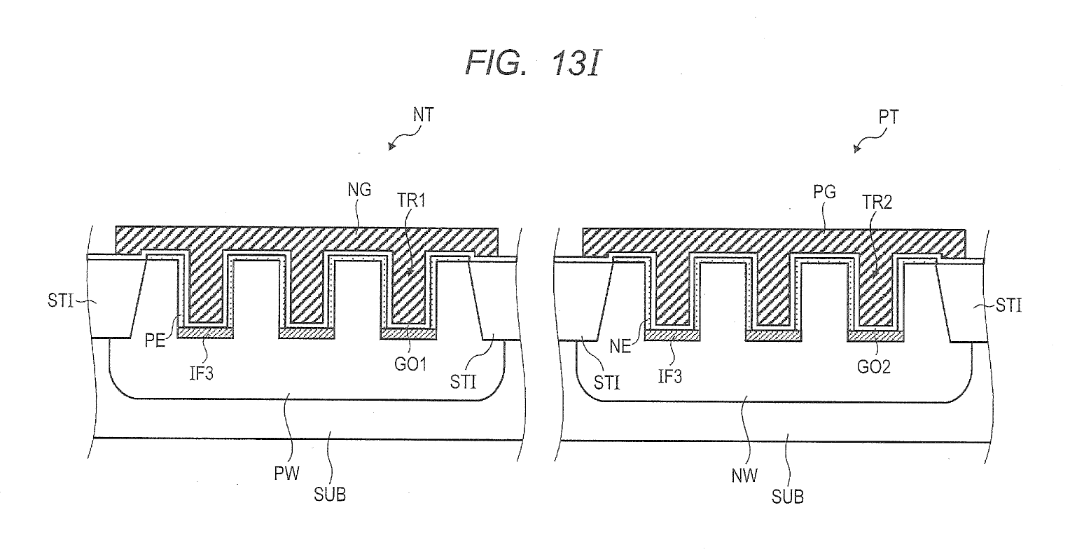

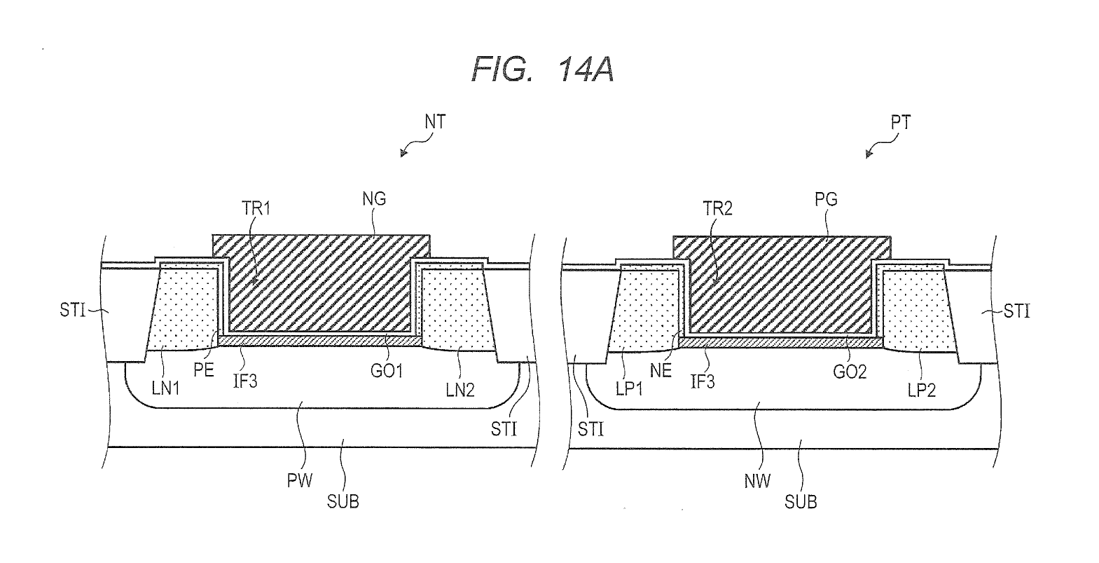

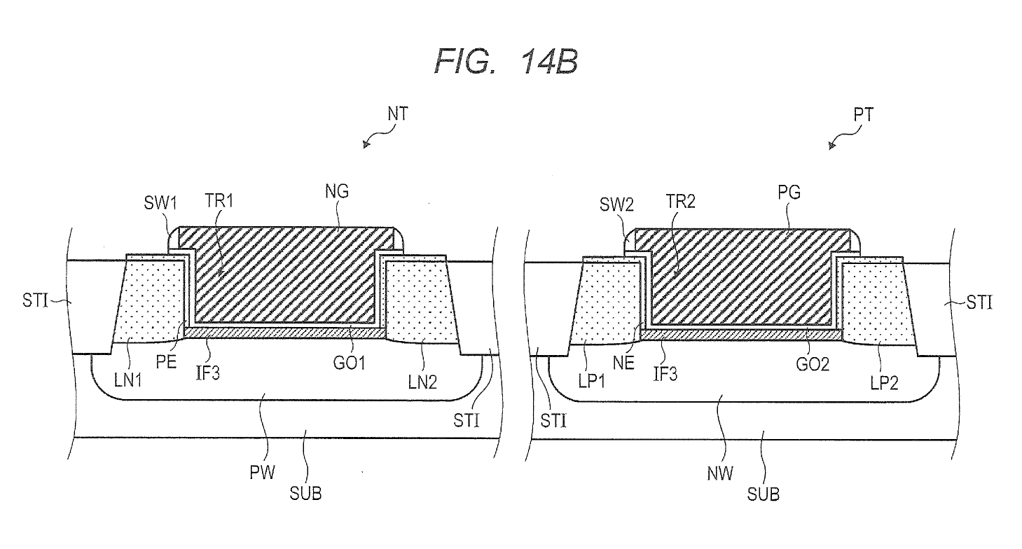

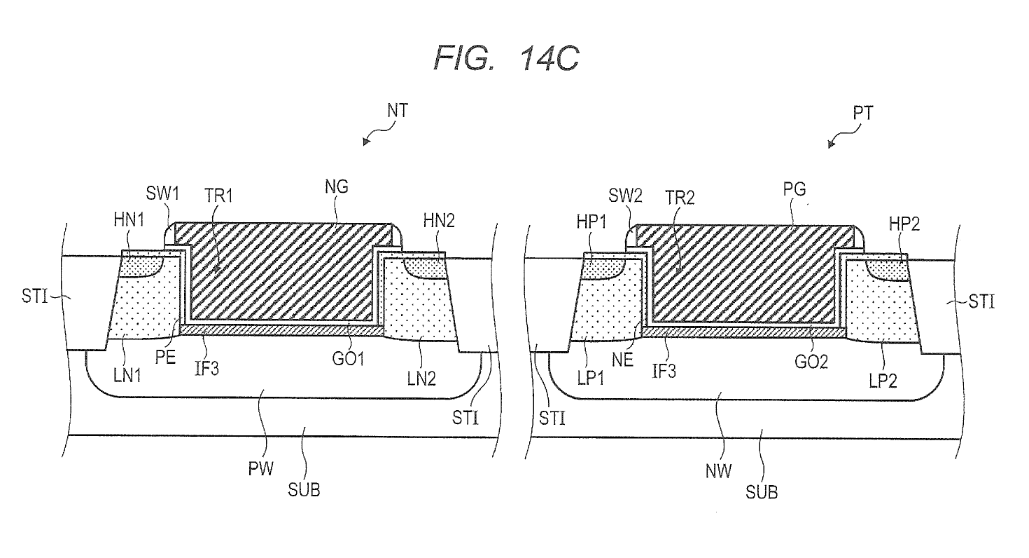

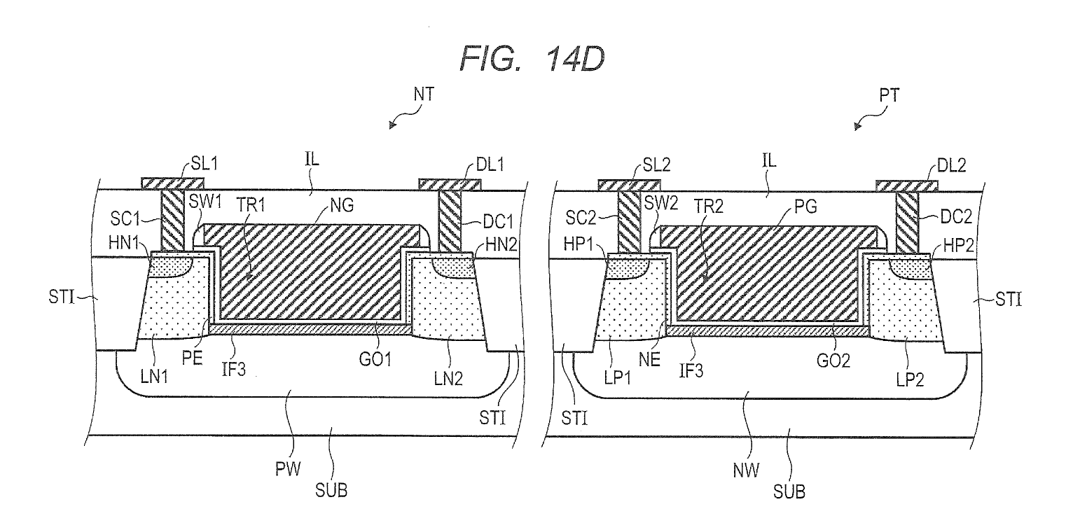

Then, a method of manufacturing the NMOS transistor NT and the PMOS transistor PT according to the third embodiment is to be described with reference to FIGS. 13A to 13I and FIGS. 14A to 14D. FIGS. 13A to 13I are cross sectional views explaining the method of manufacturing the NMOS transistor NT and the PMOS transistor PT according to the third embodiment, which correspond to the cross sectional view along the line IIc-IIc in FIG. 1 and the cross sectional view along the line IVc-IVc in FIG. 3. FIGS. 14A to 14D are cross sectional views explaining the method of manufacturing the NMOS transistor NT and the PMOS transistor PT according to the third embodiment, which correspond to the cross sectional view along the line IIa-IIa in FIG. 1 and the cross sectional view along the line IVa-IVa in FIG. 3.

Since FIGS. 13A and 13E are in common with FIGS. 9A to 9E according to the second embodiment and the manufacturing steps are also identical, description therefor is to be omitted.

Then, as illustrated in FIG. 13F, a P-type epitaxial layer PE of about 50 to 100 nm thickness is formed over the well PW by a selective epitaxial growing method under the conditions, for example, in vacuum and at a temperature of 860 to 900° C. The P-type epitaxial layer PE is formed selectively only over the surface of the well PW but is not formed over the surface of the device isolation layer STI, the insulating film IF3 left over the bottom of the trenches TR1, and the insulating film IF3 over the region for forming the PMOS transistor PT.

Then, as illustrated in FIG. 13G, a masking insulating film IF4 comprising a silicon oxide (SiO₂) of about 50 nm thickness is formed over the entire surface of the semiconductor substrate SUB by, for example, a CVD method. Then, a resist mask (not illustrated) is formed over the region for forming the NMOS transistor NT, and the insulating films IF3 and IF4 in the region for forming the PMOS transistor PT are removed by etching. After removing the resist mask, an N-type epitaxial layer NE of about 50 to 100 nm thickness is formed over the well NW by a selective epitaxial growing method under the conditions, for example, in vacuum and at a temperature of 860 to 900° C. The N-type epitaxial layer NE is formed selectively only over the surface of the well NW but is not formed over the surface of the device isolation layer STI, the insulating film IF3 left over the bottom of the trenches TR2 and the insulating film FI4 over the region for forming the NMOS transistor NT.

Then, as illustrated in FIG. 13H, after removing the insulating film IF4 over the region for forming the NMOS transistor NT by etching, gate oxide films GO1 and GO2 and gate electrodes NG and PG are formed over the entire surface of the semiconductor substrate SUB in the same manner as in the first embodiment.

Then, as illustrated in FIG. 13I, the gate electrodes NG and PG are patterned each into a desired shape by dry etching using a resist mask.

Subsequent steps are to be described with reference to FIGS. 14A to 14D.

FIG. 14A is a cross sectional view at a different cross section in the manufacturing step identical with that of FIG. 13I. Source low impurity concentration regions LN1 and LP1 and drain low impurity concentration regions LN2 and LP2 are formed after forming wells PW and NW (FIG. 14A) and before forming trenches TR1 and TR2 (FIG. 14B). Since the steps of forming the source low impurity concentration regions LN1 and LP1 and the drain low impurity concentration regions LN2 and LP2 are identical with those in the first embodiment, description therefor is to be omitted.

Then, steps after patterning the gate electrodes NG and PG illustrated in FIG. 13I and FIG. 14A are to be described.

As illustrated in FIG. 14B, side walls SW1 and SW2 are formed and, at the same time, unnecessary portions of the gate oxide films GO1 and GO2 are removed in the same manner as in the first embodiment.

Then, as illustrated in FIG. 14C, source high impurity concentration regions HN1 and HP1 and drain high impurity concentration regions HN2 and HP2 are formed in the same manner as in the first embodiment.

Finally, as illustrated in FIG. 14D, an interlayer insulating film IL, source contacts SC1 and SC2, drain contacts DC1 and DC2, source interconnects SL1 and SL2, and drain interconnects DL1 and DL2 are formed. Thus, the NMOS transistor NT and the PMOS transistor PT according to the third embodiment are obtained.

As has been described above, in the NMOS transistor NT and the PMOS transistor PT according to the third embodiment, since the epitaxial layers PE and NE are not formed over the bottom of the trenches TR1 and TR2, there is no possibility of resulting crystal defect and defective shape in the epitaxial layers PE and NE in the same manner as in the second embodiment. In addition, since the epitaxial layers PE and NE of uniform impurity concentration that serve as channel regions are provided on the lateral surfaces of the trenches TR1 and TR2 in the same manner as in the first embodiment, a threshold voltage of the transistor can be easily set to a desired value.

While the inventions made by the present inventors have been described specifically with reference to the embodiments, it will be apparent that the invention is not restricted to the embodiments but can be modified variously within a range not departing the gist thereof.

What is claimed is:

1. A transistor comprising:
a source region;
a drain region;
a plurality of trenches extended in the longitudinal direction of a channel between the source region and the drain region and arranged in parallel in the lateral direction of the channel;
an epitaxial layer formed on the lateral surfaces of the trenches;
a gate oxide film covering the epitaxial layer; and
a gate electrode covering the gate oxide film and filled in the trenches.

2. The transistor according to claim 1, wherein the epitaxial layer is not formed over the bottom of the trenches.

3. The transistor according to claim 2, wherein an insulating film formed to a layer below the gate oxide film is further provided over the bottom of the trenches.

4. The transistor according to claim 3, wherein the trenches are arranged in parallel at equal distance in the lateral direction of the channel.

5. The transistor according to claim 4, wherein the plurality of trenches each have a width identical to each other.

6. The transistor according to claim 1,
wherein the source region includes:
a first high impurity concentration region; and
a first low impurity concentration region at an impurity concentration lower than that of the first high impurity concentration region and provided in the drain region, and
wherein the drain region includes:
a second high impurity concentration region; and
a second low impurity concentration layer at an impurity concentration lower than that of the second high impurity concentration region and provided in the source region.

7. A method of manufacturing a transistor comprising:
extending a plurality of trenches in the longitudinal direction of a channel over a semiconductor layer and arranging them in parallel in the lateral direction of the channel;
forming an epitaxial layer on the lateral surfaces of the trenches;
covering the epitaxial layer by a gate oxide film; and
covering the gate oxide film and filling the trenches with the gate electrode.

8. The method of manufacturing the transistor according to claim 7, wherein the epitaxial layer is not formed over the bottom of the trenches.

9. The method of manufacturing the transistor according to claim 8, wherein an insulating film is formed over the bottom of the transistors after forming the trenches and before forming the epitaxial layer.

10. The method of manufacturing the transistor according to claim 9, wherein, upon forming the epitaxial layer, the epitaxial layer is formed by a selective epitaxial growing method.

11. The method of manufacturing a transistor according to claim 9, comprising:
upon forming the epitaxial layer,
forming an amorphous silicon layer over the semiconductor layer;
etching back the amorphous silicon layer and removing the amorphous silicon layer over the bottom of the plurality of trenches; and
epitaxializing the amorphous silicon layer.

12. The method of manufacturing the transistor according to claim 9, wherein the trenches are arranged in parallel at equal distance in the lateral direction of the channel.

13. The method of manufacturing the transistor according to claim 9, wherein the trenches are formed each at a width identical with each other.
